(19) United States
(12) Patent Application Publication
(10) Pub. No.: US 2025/0273545 A1
(43) Pub. Date: Aug. 28, 2025

(54) SEMICONDUCTOR DEVICE AND FABRICATING METHOD THEREOF

(71) Applicant: YANGTZE MEMORY TECHNOLOGIES CO., LTD., Wuhan (CN)

(72) Inventors: Dongyu Fan, Wuhan (CN); Hao Zheng, Wuhan (CN); Tingting Gao, Wuhan (CN); Yuxuan Fang, Wuhan (CN); Lei Liu, Wuhan (CN)

(21) Appl. No.: 18/666,034

(22) Filed: May 16, 2024

Related U.S. Application Data
(63) Continuation of application No. PCT/CN2024/081216, filed on Mar. 12, 2024.

(30) Foreign Application Priority Data
Feb. 26, 2024 (WO) PCT/CN2024/078561

(51) Int. Cl. H01L 23/495; H01L 21/60; H01L 23/498; H01L 25/065; H10B 80/00

(52) U.S. Cl. CPC H01L 23/49568; H01L 21/60; H01L 23/49816; H01L 25/0657; H10B 80/00; H01L 2021/60232; H01L 2225/06506; H01L 2225/06589

(57) ABSTRACT

A semiconductor device and fabricating methods thereof are disclosed. The semiconductor device includes: a plurality of dies stacked in a vertical direction; a thermal conductive layer deposited on a top surface of a topmost die; a base die located on a bottom surface of a bottommost die; and a first contact structure extending vertically through the plurality of dies. The first contact structure includes one or more first channels. Each first channel has a first end being in contact with the base die and has a second end being in contact with the thermal conductive layer.

### CROSS-REFERENCE TO RELATED APPLICATIONS

This application is a continuation of International Application No. PCT/CN2024/081216, filed on Mar. 12, 2024, entitled “SEMICONDUCTOR DEVICE AND FABRICATING METHOD THEREOF,” which claims the benefit of priority to International Application No. PCT/CN2024/078561, filed on Feb. 26, 2024, both of which are hereby incorporated by reference in their entireties.

### TECHNICAL FIELD

The present disclosure generally relates to the field of semiconductor technology, and more particularly, to packaging of semiconductor devices, and fabricating methods thereof.

### BACKGROUND

As the power consumption of semiconductor chips continues increasing, the requirements for heat dissipation of packages become higher. However, the packaging structure has poor thermal conductivity on one hand, and the existing heat dissipation methods are mostly processed at the system level on the other hand. There is a demand for special heat dissipation inside the semiconductor packages.

### SUMMARY

In one aspect, a semiconductor device is provided. The semiconductor device includes a plurality of dies stacked in a vertical direction; a thermal conductive layer deposited on a top surface of a topmost die; a base die located on a bottom surface of a bottommost die; and a first contact structure extending vertically through the plurality of dies. The first contact structure includes one or more first channels, each first channel having a first end being in contact with the base die and having a second end being in contact with the thermal conductive layer.

In some implementations, the semiconductor device further includes a second contact structure extending vertically inside the plurality of dies. The second contact structure includes one or more second channels, each second channel extending vertically and being in contact with the base die without contacting the thermal conductive layer.

In some implementations, the base die includes a wiring structure including a first wiring structure and a second wiring structure. The first wiring structure is configured to transport heat and the second wiring structure is configured to transmit electronic signals.

In some implementations, the semiconductor device further includes an interposer on a side of the base die opposite to the plurality of dies. The interposer includes a ball grid array on a side of the interposer opposite to the base dies.

In some implementations, the ball grid array includes one or more thermal solder balls in connection with the first wiring structure and one or more signal solder balls in connection with the second wiring structure.

In some implementations, each of the first channel and the second channel is a continuous structure along the vertical direction.

In some implementations, the second contact structure is surrounded by the first contact structure.

In some implementations, the first end of each first channel has a first lateral dimension, the second end of each first channel has a second lateral dimension, and the first lateral dimension is larger than the second lateral dimension.

In some implementations, each second channel has a first end in contact with the base die, the first end of each second channel has a third lateral dimension, and the third lateral dimension is smaller than a first lateral dimension of the first end of each first channel.

In some implementations, the first lateral dimension is 2-3 μm and the third lateral dimension is less than 2 μm.

In some implementations, the semiconductor device further includes a high operating power consumption region and a low operating power consumption region. A quantity of first channels in the high operating power consumption region is greater than a quantity of first channels in the low operating power consumption region.

In some implementations, a material of the thermal conductive layer has a thermal conductivity of no less than 20 W/mK.

In some implementations, the material of the thermal conductive layer is one of silicon nitride, aluminum oxide, and silicon carbide.

In some implementations, the plurality of dies includes at least one memory die, and the plurality of dies are stacked through direct bonding.

In another aspect, another semiconductor device is provided. The semiconductor device includes a plurality of dies stacked in a vertical direction; an interposer located on a bottom surface of a base die, where the interposer includes a wiring structure including a first wiring structure and a second wiring structure; and a first contact structure extending vertically through the plurality of dies. The first contact structure includes one or more first channels, each first channel having a first end being in contact with the interposer and having a second end being in contact with a top surface of a topmost die.

In some implementations, the semiconductor device includes a second contact structure extending vertically inside the plurality of dies. The second contact structure includes one or more second channels, each second channel extending vertically and being in contact with the interposer without contacting the top surface of the topmost die.

In some implementations, the semiconductor device includes a ball grid array on a side of the interposer opposite to the plurality of dies.

In some implementations, the ball grid array includes one or more thermal solder balls in contact with the first wiring structure, where the first wiring structure is configured to transport heat; and one or more signal solder balls in contact with the second wiring structure, where the second wiring structure is configured to transmit electronic signals.

In some implementations, each of the first channel and the second channel is a continuous structure along the vertical direction.

In some implementations, the second contact structure is surrounded by the first contact structure.

In some implementations, the first end of each first channel has a first lateral dimension, the second end of each first channel has a second lateral dimension, and the first lateral dimension is larger than the second lateral dimension.

In some implementations, each second channel has a first end in contact with the interposer, the first end of each second channel has a third lateral dimension, and the third lateral dimension is smaller than a first lateral dimension of the first end of each first channel.

In some implementations, the first lateral dimension is 2-3 μm and the third lateral dimension is less than 2 μm.

In some implementations, the semiconductor device includes a high operating power consumption region and a low operating power consumption region. A quantity of first channels in the high operating power consumption region is greater than a quantity of first channels in the low operating power consumption region.

In some implementations, a material of the first channels has a thermal conductivity of no less than 20 W/mK.

In some implementations, the material of the first channels is one of silicon nitride, aluminum oxide, and silicon carbide.

In some implementations, the plurality of dies include at least one memory die, and the plurality of dies are stacked through direct bonding.

In still another aspect, a method is provided. The method includes: stacking a plurality of dies in a vertical direction; depositing a sacrificial layer on a first surface of the stacked dies, and forming a plurality of first holes in the sacrificial layer; forming, using the plurality of first holes, a first contact structure extending vertically through the stacked dies, where the first contact structure includes one or more first channels; bonding a base die on the first surface of the stacked dies through hybrid bonding; bonding an interposer on the base die, where the interposer includes a wiring structure; connecting each first channel with the wiring structure; and forming a thermal conductive layer on a second surface of the stacked die, where the second surface is opposite to the first surface in the vertical direction, and the thermal conductive layer is physically connected with each first channel.

In some implementations, the method further includes: forming a plurality of second holes in the sacrificial layer; forming, using the plurality of second holes, a second contact structure extending vertically inside the stacked dies, where the second contact structure includes one or more second channels; and connecting each second channel with the interposer without physically contacting the thermal conductive layer.

In some implementations, the method further includes forming a ball grid array on a side of the interposer opposite to the stacked dies.

In some implementations, the wiring structure includes a first wiring structure configured to transport heat and a second wiring structure configured to transmit electronic signals, and forming the ball grid array includes: forming a plurality of thermal solder balls in contract with the first wiring structure; and forming a plurality of signal solder balls in contact with the second wiring structure.

In some implementations, forming the first contact structure includes forming each first channel continuously extending along the vertical direction; and forming the second contact structure includes forming each second channel continuously extending along the vertical direction.

In some implementations, forming the second contact structure includes forming the second contact structure surrounded by the first contact structure.

In some implementations, the method further includes forming each first channel with a first end having a first lateral dimension and a second end having a second lateral dimension. The first end of each first channel is in contact with the base die, the second end of each first channel is in contact with the thermal conductive layer, and the first lateral dimension is larger than the second lateral dimension.

In some implementations, the method further includes forming each second channel with a first end having a third lateral dimension. The first end of each second channel is contact with the base die and the third lateral dimension is smaller than the first lateral dimension.

In some implementations, forming the thermal conductive layer includes using a material having a thermal conductivity of no less than 20 W/mK.

In some implementations, forming the thermal conductive layer includes using one of silicon nitride, aluminum oxide, and silicon carbide.

In some implementations, stacking the plurality of dies includes stacking at least one memory die with other dies through direct bonding.

### BRIEF DESCRIPTION OF THE DRAWINGS

The accompanying drawings, which are incorporated herein and form a part of the specification, illustrate implementations of the present disclosure and, together with the description, serve to explain the principles of the present disclosure and to enable a person skilled in the pertinent art to make and use the present disclosure.

FIG. 1A illustrates a schematic diagram in a perspective side view of a first exemplary semiconductor device, in accordance with some implementations of the present disclosure.

FIG. 1B illustrates a schematic diagram in a perspective side view of a second exemplary semiconductor device, in accordance with some implementations of the present disclosure.

FIG. 1C illustrates a schematic diagram in a perspective side view of a third exemplary semiconductor device, in accordance with some implementations of the present disclosure.

FIGS. 2A-2F illustrate a fabrication process for forming a first semiconductor device according to some aspects of the present disclosure.

FIGS. 3A-3F illustrate a fabrication process for forming a second semiconductor device according to some aspects of the present disclosure.

FIGS. 4A-4G illustrate a fabrication process for forming a third semiconductor device according to some aspects of the present disclosure.

FIGS. 5A-5B illustrate schematic diagrams in a planar view of an exemplary semiconductor device, in accordance with some other implementations of the present disclosure.

FIG. 6 illustrates a flow diagram of an exemplary method for forming a first semiconductor device, in accordance with some implementations of the present disclosure.

FIG. 7 illustrates a flow diagram of an exemplary method for forming a second semiconductor device, in accordance with some implementations of the present disclosure.

FIG. 8 illustrates a flow diagram of an exemplary method for forming a third semiconductor device, in accordance with some implementations of the present disclosure.

FIG. 9 illustrates a block diagram of an example system having one or more semiconductor devices, in accordance with some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure, or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures, or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The front surface of the substrate is typically where a semiconductor device is formed, and therefore the semiconductor device is formed at a top side of the substrate unless stated otherwise. The bottom surface is opposite to the front surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is adjacent to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

The present disclosure provides semiconductor devices with a high thermal conductivity. In the era of great computing power and artificial intelligence (AI), the von Neumann architecture that combines high-bandwidth memory (HBM) with GPU remains the mainstream in the high-performance chip market. However, the high amount of heat generated by the stacked HBM is an urgent issue that needs to be addressed. In the traditional HBM architecture, as the number of stacked DRAM layers increases, the heat dissipation for different layers of DRAM varies, which can easily lead to slow heat dissipation for DRAMs located in the middle, causing a decline in performance. Because DRAM needs to continuously perform read and write operations, it tends to generate heat during operation. The stacked structure of HBM limits the heat dissipation of the DRAM located in the middle layers.

In the semiconductor devices provided by this disclosure, the heat generated during the operation of HBM can be rapidly dissipated to prevent localized overheating. The number of I/O channels can be significantly increased. Compared to some existing semiconductor devices, the disclosed semiconductor devices can achieve better internal heat dissipation inside stacked dies without increasing the chip area of the HBM.

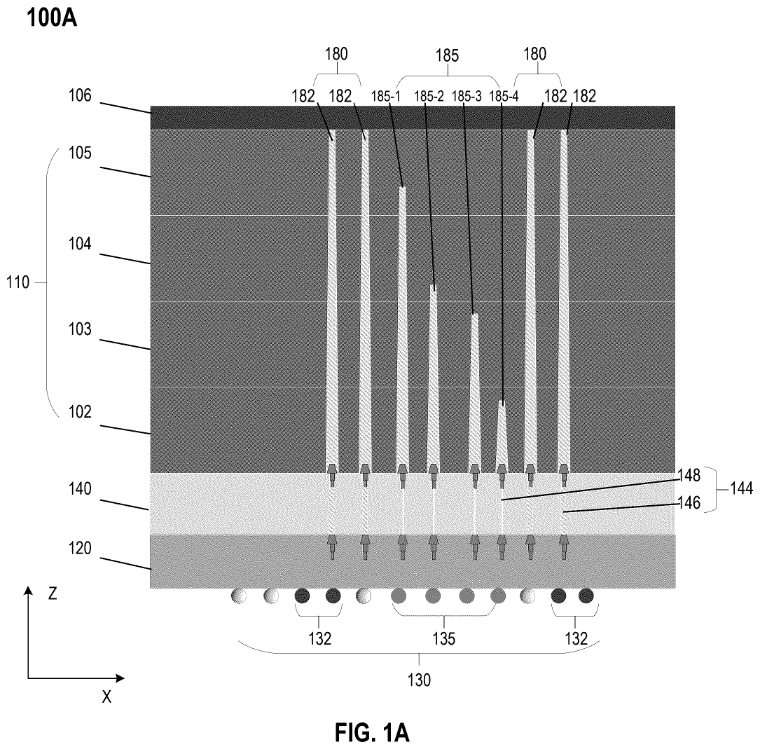

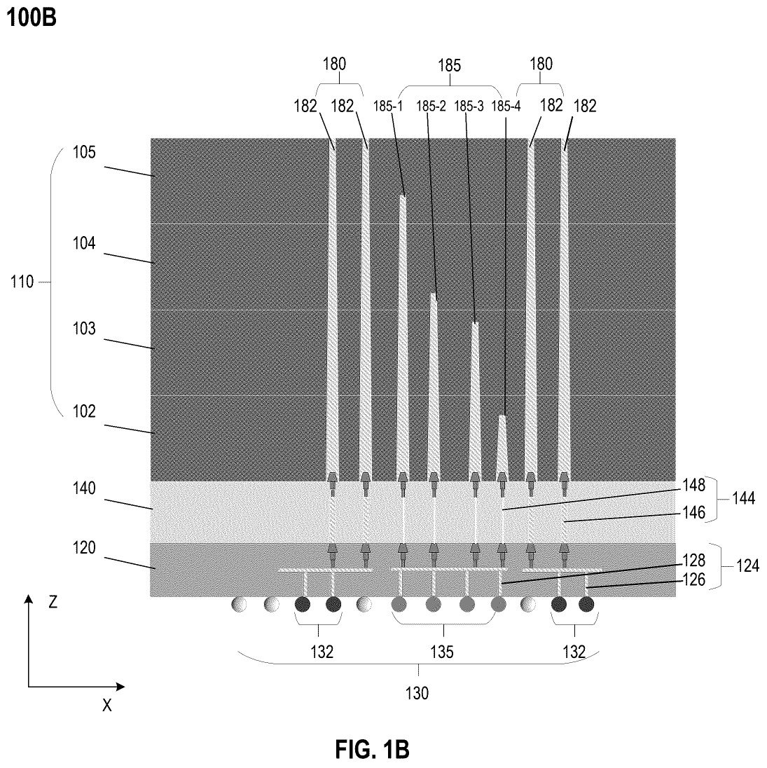

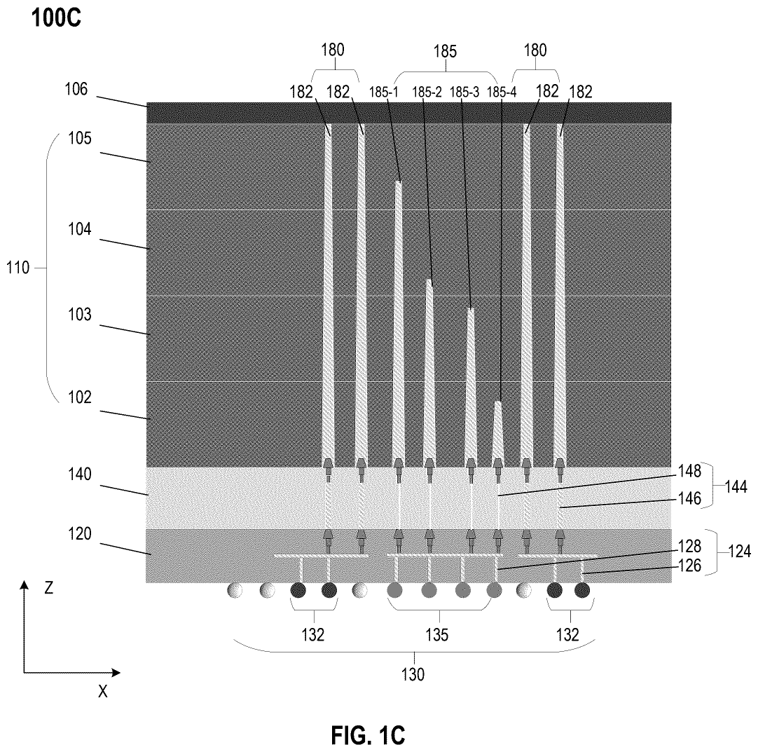

FIG. 1A shows a schematic diagram in a perspective side view of a first exemplary semiconductor device, in accordance with some implementations of the present disclosure. As shown in FIG. 1A, semiconductor device 100A can include an interposer 120, a base die 140 on a first side of the interposer 120, stacked dies 110 on a first side of the base die 140, and a ball grid array (BGA) 130 on a second side of the interposer 120 opposite to the first side. It is noted that, the semiconductor device 100A can further include any other suitable components that are not shown in FIG. 1A. For example, the semiconductor device can further include a printed circuit board (PCB) on which the semiconductor device 100A is mounted via the BGA 130.

The interposer 120 can be any suitable semiconductor material having any suitable structure, such as a monocrystalline single-layer material, a polycrystalline silicon (polysilicon) single-layer material, a polysilicon and metal multi-layer material, etc.

The base die 140 can include wiring structure 144, which includes first wiring structure 146 and second wiring structure 148 embedded in the base die. The first wiring structure 146 can include any suitable thermal conductive interconnection structures, such as conductive vias and patterned conductive layers, etc., and configured to transport heat. The second wiring structure 148 can include any suitable conductive interconnection structures, such as conductive channels, and configured to transmit electronic signals. In some implementations, the second wiring structure 148 can be configured to transmit both electronic signals and heat. The first wiring structure 146 and the second wiring structure 148 can be isolated from each other.

In some implementations, the first wiring structure 146 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 148 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 146 and a second wiring width of the second wiring structure 148 can be in a range between about 1.5:1 to about 2:1.

The stacked dies 110 can include a plurality of dies stacked vertically through direct bonding, which forms bonding between surfaces without using intermediate layers, such as solder or adhesives. The stacked dies can be attached to a first side of the base die 140 by an adhesive film (not shown). Exemplarily, the stacked dies 110 include die 102, die 103, die 104, and die 105. In some implementations, the stacked dies 110 can be any suitable semiconductor dies/die including one or more memory dies. The stacked dies 110 can include low power chips having maximum operation powers lower than a threshold power value. The stacked dies can include high power chips having maximum operation powers higher than the threshold power value. For example, the stacked dies 110 include at least one of a micro processing chip, a logic control chip, a power management chip, a driver chip, and an analog chip, and may also include at least one of a memory chip and a sensing chip. In some implementations, the adhesive film can be any suitable die attach film (DAF).

In some implementations, the semiconductor device includes a first contact structure 180 extending vertically in the stacked dies. The first contact structure can include one or more first channels 182, and each first channel 182 is a continuous channel that has a first end in connection with the first wiring structure 146 and a second end in contact with a top surface of a topmost die of the stacked dies. The first end of each first channel 182 has a first lateral dimension (e.g., x-direction), the second end of each first channel 182 has a second lateral dimension (e.g., x-direction), and the first lateral dimension is larger than the second lateral dimension. In some implementations, the first lateral dimension is about 2-3 μm. In some implementations, the material of each first channel has a thermal conductive coefficient of no less than 20 W/mK. In some implementations, the material of each first channel is one of a metal, a ceramic material, or a silicon material. In some implementations, the material of each first channel can be one of silicon nitride, aluminum oxide, and silicon carbide.

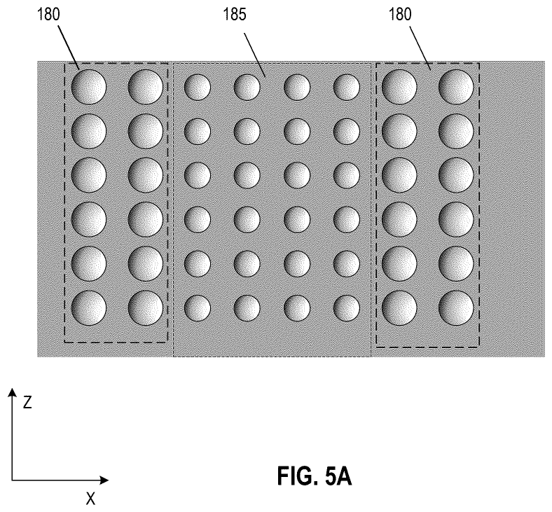

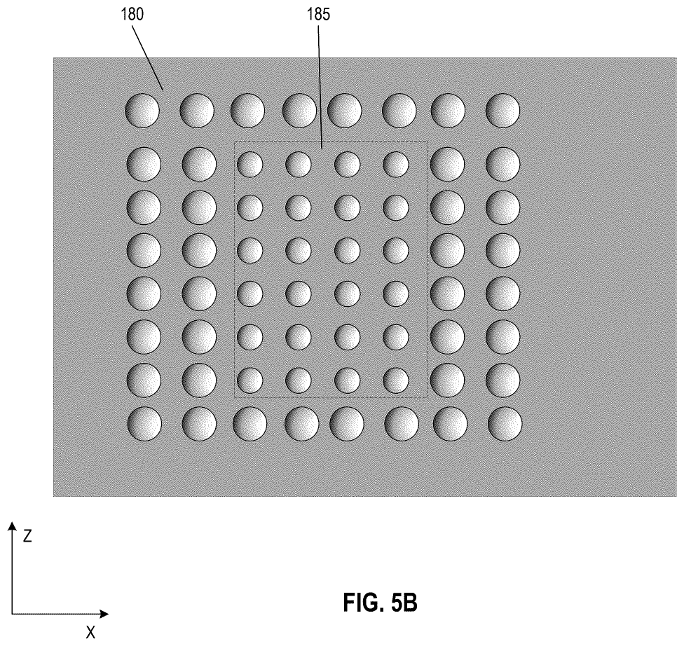

In some implementations, the semiconductor device includes a second contact structure 185 extending vertically in the stacked dies. The second contact structure 185 can be sandwiched between two first contact structures 180 as shown in FIG. 5A, or can be surrounded by the first contact structure 180 as shown in FIG. 5B. The second contact structure 185 can include a plurality of second channels, and each second channel of second contact structure 185 is a continuous channel that has a first end in contact with the second wiring structure 148 and a second end inside the stacked dies without contacting the top surface of the topmost die of the stacked dies. The first end of each second channel of second contact structure 185 has a third lateral dimension (e.g., x-direction), and the third lateral dimension is smaller than the first lateral dimension of the first end of each first channel. In some implementations, the third lateral dimension is less than 2 μm. In some implementations, the plurality of second channels have different dimensions along the vertical direction. For example, second channel 185-1 has a first end in contact with the second wiring structure 148 and a second end inside the die 105 without contacting the top surface of die 105; second channel 185-2 has a first end in contact with the second wiring structure 148 and a second end inside die 104 without contacting the top surface of die 104; second channel 185-3 has a first end in contact with the second wiring structure 148 and a second end inside die 103 without contacting the top surface of die 103; and second channel 185-4 has a first end in contact with the second wiring structure 148 and a second end inside die 102 without contacting the top surface of die 102. In some implementations, the material of each second channel is one of a metal, a ceramic material, or a silicon material.

In some implementations, a thermal conductive layer 106 can cover the top surface of the topmost die, so that the thermal conductive layer 106 is in contact with each first channel 182. The material of the thermal conductive layer 106 has a thermal conductive coefficient of no less than 20 W/mK. In some implementations, the material of the thermal conductive layer 106 is one of a metal, a ceramic material, or a silicon material. In some implementations, the material of each first channel can be one of silicon nitride, aluminum oxide, and silicon carbide.

In some implementations, the ball grid array (BGA) 130 can include a plurality of solder balls 132/135 attached on a second side of the interposer opposite to the first side. BGA 130 can include a plurality of thermal solder balls 132 configured to transport heat, and a plurality of signal solder balls 135 configured to transmit electronic signals.

In some implementations, the thermal solder balls 132 and the signal solder balls 135 can comprise same materials, and can be formed in a same process. For example, the thermal solder balls 132 and the signal solder balls 135 can include any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the thermal solder balls 132 and the signal solder balls 135 can include different materials. For example, the thermal solder balls 132 can include a first material with a high thermal conductive coefficient, while the signal solder balls 135 can include a second material with a high electric conductive coefficient.

FIG. 1B shows a schematic diagram in a perspective side view of a second exemplary semiconductor device, in accordance with some implementations of the present disclosure. As shown in FIG. 1B, semiconductor device 100B can include an interposer 120, a base die 140 on a first side of the interposer 120, stacked dies 110 on a first side of the base die 140, and a ball grid array (BGA) 130 on a second side of the interposer 120 opposite to the first side. It is noted that, the semiconductor device 100B can further include any other suitable components that are not shown in FIG. 1B. For example, the semiconductor device can further include a printed circuit board (PCB) on which the semiconductor device 100B is mounted via the BGA 130.

The interposer 120 can be any suitable semiconductor material having any suitable structure, such as a monocrystalline single-layer material, a polycrystalline silicon (polysilicon) single-layer material, a polysilicon and metal multi-layer material, etc. The interposer 120 can include connecting structure 124, which includes first connecting structure 126 and second connecting structure 128 embedded in the interposer 120. The first connecting structure 126 can include any suitable thermal conductive interconnection structures, such as conductive vias and patterned conductive layers, etc., and is configured to transport heat. The second connecting structure 128 can include any suitable conductive interconnection structures, such as conductive channels, and is configured to transmit electronic signals. In some implementations, the second connecting structure 128 can be configured to transmit both electronic signals and heat. The first connecting structure 126 and the second connecting structure 128 can be isolated from each other.

In some implementations, the first connecting structure 126 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second connecting structure 128 can comprise any suitable conductive materials, such as Ag, Cu, aluminum (Al), aluminum nitride, silicon carbide, W, graphite, zinc (Zn), combinations thereof, and/or other materials known to those skilled in the art.

The base die 140 can include wiring structure 144, which includes first wiring structure 146 and second wiring structure 148 embedded in the base die. The first wiring structure 146 can include any suitable thermal conductive interconnection structures, such as conductive vias and patterned conductive layers, etc., and configured to transport heat. The second wiring structure 148 can include any suitable conductive interconnection structures, such as conductive channels, and configured to transmit electronic signals. In some implementations, the second wiring structure 148 can be configured to transmit both electronic signals and heat. In some implementations, the first wiring structure 146 is physically connected with the first connecting structure 126, and the second wiring structure 148 is physically connected with the second connecting structure 128. The first wiring structure 146 and the second wiring structure 148 can be isolated from each other.

In some implementations, the first wiring structure 146 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 148 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 146 and a second wiring width of the second wiring structure 148 can be in a range between about 1.5:1 to about 2:1.

The stacked dies 110 can include a plurality of dies stacked vertically through direct bonding, which forms bonding between surfaces without using intermediate layers, such as solder or adhesives. The stacked dies are attached to a first side of the base die 140 by an adhesive film (not shown). Exemplarily, the stacked dies 110 include die 102, die 103, die 104, and die 105. In some implementations, the stacked dies 110 can be any suitable semiconductor dies/die including one or more memory dies. The stacked dies 110 can include low power chips having maximum operation powers lower than a threshold power value. The stacked dies can include high power chips having maximum operation powers higher than the threshold power value. For example, the stacked dies 110 include at least one of a micro processing chip, a logic control chip, a power management chip, a driver chip, and an analog chip, and may also include at least one of a memory chip and a sensing chip. In some implementations, the adhesive film can be any suitable die attach film (DAF).

In some implementations, the semiconductor device includes a first contact structure 180 extending vertically in the stacked dies. The first contact structure can include one or more first channels 182, and each first channel 182 is a continuous channel that has a first end in connection with the first wiring structure 146 and a second end in contact with a top surface of a topmost die of the stacked dies. The first end of each first channel 182 has a first lateral dimension (e.g., x-direction), the second end of each first channel 182 has a second lateral dimension (e.g., x-direction), and the first lateral dimension is larger than the second lateral dimension. In some implementations, the first lateral dimension is about 2-3 μm. In some implementations, the material of each first channel has a thermal conductive coefficient of no less than 20 W/mK. In some implementations, the material of each first channel is one of a metal, a ceramic material, or a silicon material. In some implementations, the material of each first channel can be one of silicon nitride, aluminum oxide, and silicon carbide.

In some implementations, the semiconductor device includes a second contact structure 185 extending vertically in the stacked dies. The second contact structure 185 can be sandwiched between two first contact structures 180 as shown in FIG. 5A, or can be surrounded by the first contact structure 180 as shown in FIG. 5B. The second contact structure 185 can include a plurality of second channels, and each second channel of second contact structure 185 is a continuous channel that has a first end in contact with the second wiring structure 148 and a second end inside the stacked dies without contacting the top surface of the topmost die of the stacked dies. The first end of each second channel 185 has a third lateral dimension (e.g., x-direction), and the third lateral dimension is smaller than the first lateral dimension of the first end of each first channel. In some implementations, the third lateral dimension is less than 2 μm. In some implementations, the plurality of second channels have different dimensions along the vertical direction. For example, second channel 185-1 has a first end in contact with the second wiring structure 148 and a second end inside the die 105 without contacting the top surface of die 105; second channel 185-2 has a first end in contact with the second wiring structure 148 and a second end inside die 104 without contacting the top surface of die 104; second channel 185-3 has a first end in contact with the second wiring structure 148 and a second end inside die 103 without contacting the top surface of die 103; and second channel 185-4 has a first end in contact with the second wiring structure 148 and a second end inside die 102 without contacting the top surface of die 102. In some implementations, the material of each second channel is one of a metal, a ceramic material, or a silicon material.

In some implementations, the ball grid array (BGA) 130 can include a plurality of solder balls 132/135 attached on a second side of the interposer opposite to the first side. BGA 130 can include a plurality of thermal solder balls 132 in contact with the first connecting structure 126, and a plurality of signal solder ball 135 in contact with the second connecting structure 128. That is, the thermal solder balls 132 can be coupled with the first contact structure 180 via the first wiring structure 146 and first connecting structure 126, and are configured to dissipate heat in the stacked dies. The signal solder balls 135 can be coupled with the second contact structure 185 via the second wiring structure 148 and the second connecting structure 128, and are configured to transmit electronic signals between the stacked dies and the PCB.

In some implementations, the thermal solder balls 132 and the signal solder balls 135 can comprise same materials, and can be formed in a same process. For example, the thermal solder balls 132 and the signal solder balls 135 can include any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the thermal solder balls 132 and the signal solder balls 135 can include different materials. For example, the thermal solder balls 132 can include a first material with a high thermal conductive coefficient, while the signal solder balls 135 can include a second material with a high electric conductive coefficient.

FIG. 1C shows a schematic diagram in a perspective side view of a third exemplary semiconductor device, in accordance with some implementations of the present disclosure. As shown in FIG. 1C, semiconductor device 100C can include an interposer 120, a base die 140 on a first side of the interposer 120, stacked dies 110 on a first side of the base die 140, and a ball grid array (BGA) 130 on a second side of the interposer 120 opposite to the first side. It is noted that, the semiconductor device 100C can further include any other suitable components that are not shown in FIG. 1C. For example, the semiconductor device can further include a printed circuit board (PCB) on which the semiconductor device 100C is mounted via the BGA 130.

The interposer 120 can be any suitable semiconductor material having any suitable structure, such as a monocrystalline single-layer material, a polycrystalline silicon (polysilicon) single-layer material, a polysilicon and metal multi-layer material, etc. The interposer 120 can include connecting structure 124, which includes first connecting structure 126 and second connecting structure 128 embedded in the interposer 120. The first connecting structure 126 can include any suitable thermal conductive interconnection structures, such as conductive vias and patterned conductive layers, etc., and is configured to transport heat. The second connecting structure 128 can include any suitable conductive interconnection structures, such as conductive channels, and is configured to transmit electronic signals. In some implementations, the second connecting structure 128 can be configured to transmit both electronic signals and heat. The first connecting structure 126 and the second connecting structure 128 can be isolated from each other.

In some implementations, the first connecting structure 126 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second connecting structure 128 can comprise any suitable conductive materials, such as Ag, Cu, aluminum (Al), aluminum nitride, silicon carbide, W, graphite, zinc (Zn), combinations thereof, and/or other materials known to those skilled in the art.

The base die 140 can include wiring structure 144, which includes first wiring structure 146 and second wiring structure 148 embedded in the base die. The first wiring structure 146 can include any suitable thermal conductive interconnection structures, such as conductive vias and patterned conductive layers, etc., and configured to transport heat. The second wiring structure 148 can include any suitable conductive interconnection structures, such as conductive channels, and configured to transmit electronic signals. In some implementations, the second wiring structure 148 can be configured to transmit both electronic signals and heat. In some implementations, the first wiring structure 146 is physically connected with the first connecting structure 126, and the second wiring structure 148 is physically connected with the second connecting structure 128. The first wiring structure 146 and the second wiring structure 148 can be isolated from each other.

In some implementations, the first wiring structure 146 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 148 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 146 and a second wiring width of the second wiring structure 148 can be in a range between about 1.5:1 to about 2:1.

The stacked dies 110 can include a plurality of dies stacked vertically through direct bonding, which forms bonding between surfaces without using intermediate layers, such as solder or adhesives. The stacked dies 110 can be attached to a first side of the base die 140 by an adhesive film (not shown). Exemplarily, the stacked dies 110 include die 102, die 103, die 104, and die 105. In some implementations, the stacked dies 110 can be any suitable semiconductor dies/die including one or more memory dies. The stacked dies can include low power chips having maximum operation powers lower than a threshold power value. The stacked dies can include high power chips having maximum operation powers higher than the threshold power value. For example, the stacked dies 110 include at least one of a micro processing chip, a logic control chip, a power management chip, a driver chip, and an analog chip, and may also include at least one of a memory chip and a sensing chip. In some implementations, the adhesive film can be any suitable die attach film (DAF).

In some implementations, the semiconductor device includes a first contact structure 180 extending vertically in the stacked dies. The first contact structure can include one or more first channels 182, and each first channel 182 is a continuous channel that has a first end in connection with the first wiring structure 146 and a second end in contact with a top surface of a topmost die of the stacked dies. The first end of each first channel 182 has a first lateral dimension (e.g., x-direction), the second end of each first channel 182 has a second lateral dimension (e.g., x-direction), and the first lateral dimension is larger than the second lateral dimension. In some implementations, the first lateral dimension is about 2-3 μm. In some implementations, the material of each first channel has a thermal conductive coefficient of no less than 20 W/mK. In some implementations, the material of each first channel is one of a metal, a ceramic material, or a silicon material. In some implementations, the material of each first channel can be one of silicon nitride, aluminum oxide, and silicon carbide.

In some implementations, the semiconductor device includes a second contact structure 185 extending vertically in the stacked dies. The second contact structure 185 can be sandwiched between two first contact structures 180 as shown in FIG. 5A, or can be surrounded by the first contact structure 180 as shown in FIG. 5B. The second contact structure 185 can include a plurality of second channels, and each second channel of second contact structure 185 is a continuous channel that has a first end in contact with the second wiring structure 148 and a second end inside the stacked dies without contacting the top surface of the topmost die of the stacked dies. The first end of each second channel 185 has a third lateral dimension (e.g., x-direction), and the third lateral dimension is smaller than the first lateral dimension of the first end of each first channel. In some implementations, the third lateral dimension is less than 2 μm. In some implementations, the plurality of second channels have different dimensions along the vertical direction. For example, second channel 185-1 has a first end in contact with the second wiring structure 148 and a second end inside the die 105 without contacting the top surface of die 105; second channel 185-2 has a first end in contact with the second wiring structure 148 and a second end inside die 104 without contacting the top surface of die 104; second channel 185-3 has a first end in contact with the second wiring structure 148 and a second end inside die 103 without contacting the top surface of die 103; and second channel 185-4 has a first end in contact with the second wiring structure 148 and a second end inside die 102 without contacting the top surface of die 102. In some implementations, the material of each second channel is one of a metal, a ceramic material, or a silicon material.

In some implementations, a thermal conductive layer 106 can cover the top surface of the topmost die, so that the thermal conductive layer 106 is in contact with each first channel. A material of the thermal conductive layer 106 has a thermal conductive coefficient no less than 20 W/mK. In some implementations, the material of the thermal conductive layer 106 is one of a metal, a ceramic material, or a silicon material.

In some implementations, the ball grid array (BGA) 130 can include a plurality of solder balls 132/135 attached on a second side of the interposer opposite to the first side. BGA 130 can include a plurality of thermal solder balls 132 in contact with the first connecting structure 126, and a plurality of signal solder ball 135 in contact with the second connecting structure 128. That is, the thermal solder balls 132 can be coupled with the first contact structure 180 via the first wiring structure 146 and first connecting structure 126, and are configured to dissipate heat in the stacked dies. The signal solder balls 135 can be coupled with the second contact structure 185 via the second wiring structure 148 and the second connecting structure 128, and are configured to transmit electronic signals between the stacked dies and the PCB.

In some implementations, the thermal solder balls 132 and the signal solder balls 135 can comprise same materials, and can be formed in a same process. For example, the thermal solder balls 132 and the signal solder balls 135 can include any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the thermal solder balls 132 and the signal solder balls 135 can include different materials. For example, the thermal solder balls 132 can include a first material with a high thermal conductive coefficient, while the signal solder balls 135 can include a second material with a high electric conductive coefficient.

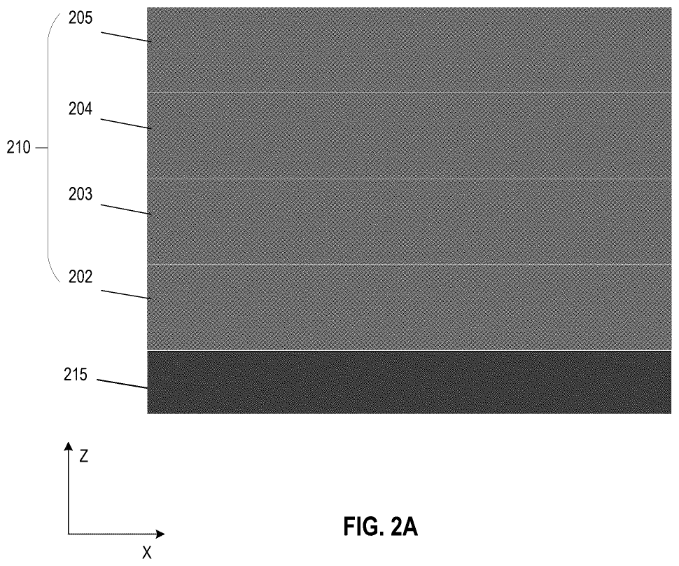

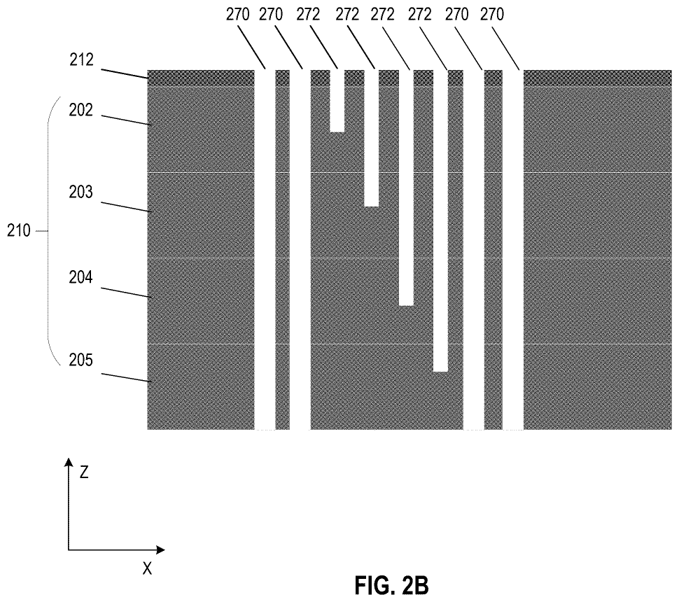

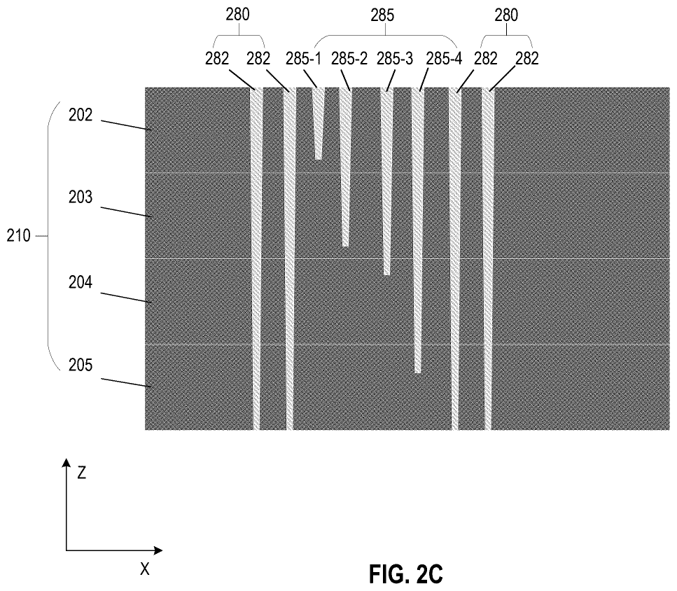

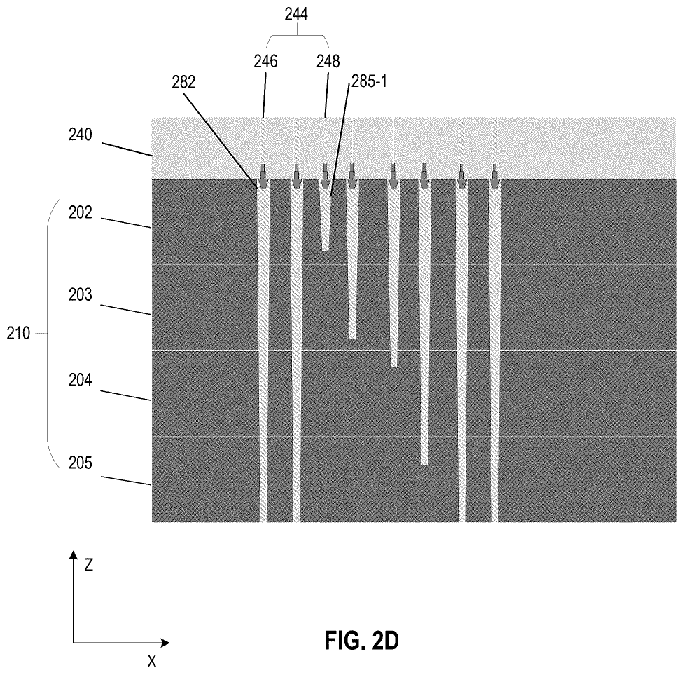

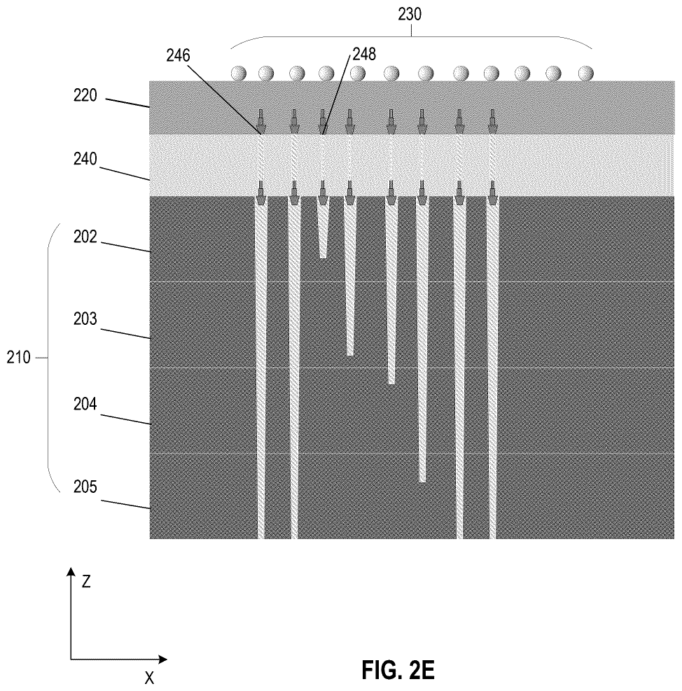

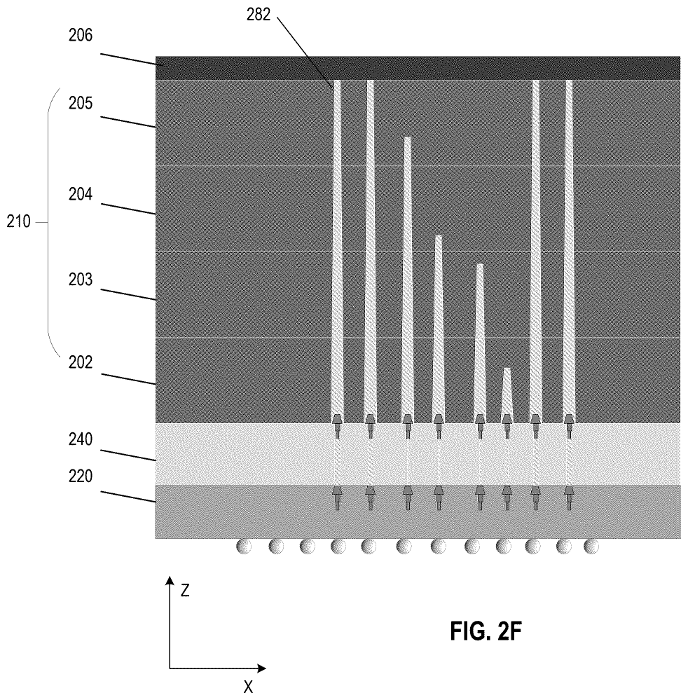

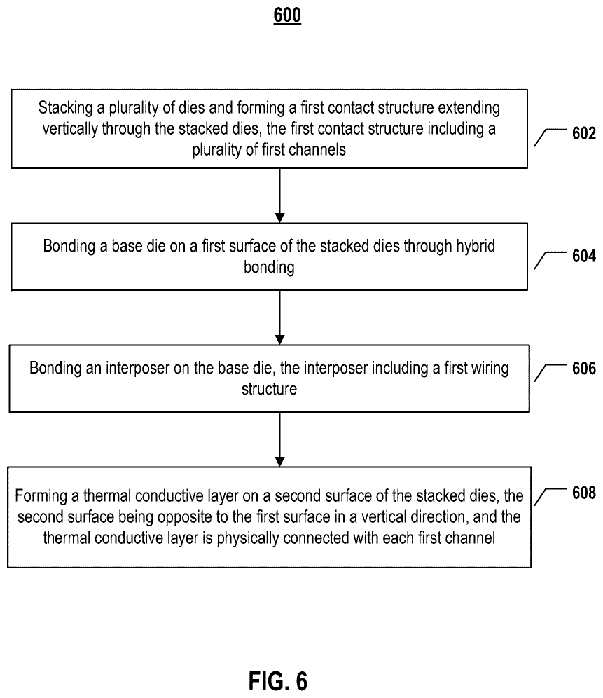

Referring to FIG. 6, a flow diagram of an exemplary method for forming a first semiconductor device is illustrated in accordance with some implementations of the present disclosure. It should be understood that the operations and/or steps shown in FIG. 6 are not exhaustive and that other operations can be performed as well before, after, or between any of the illustrated operations. FIGS. 2A-2F illustrate schematic diagrams in a perspective side view of an exemplary semiconductor device at certain fabricating steps of the method shown in FIG. 6, in accordance with some implementations of the present disclosure.

As shown in FIG. 6, the method 600 starts at operation 602, in which a plurality of dies are stacked along a vertical direction. A first contact structure is formed in the stacked dies. The first contact structure includes a plurality of first channels, each extending vertically through the stacked dies. FIGS. 2A-2C illustrate schematic diagrams in a perspective side view of exemplary semiconductor devices during operation 602 of the method 600 shown in FIG. 6, in accordance with some implementations of the present disclosure.

As shown in FIG. 2A, in some implementations, a plurality of dies are stacked through direct bonding, which forms bonding between surfaces without using intermediate layers, such as solder or adhesives, in a vertical direction on a carrier wafer 215. Exemplarily, as shown in FIG. 2A, die 202, die 203, die 204, and die 205 are stacked vertically through direct bonding, which forms bonding between surfaces without using intermediate layers, such as solder or adhesives, on the carrier wafer 215 to form stacked dies 210. In some implementations, the stacked dies 210 can be any suitable semiconductor dies/die including one or more memory dies. The stacked dies 210 can include low power chips having maximum operation powers lower than a threshold power value. The stacked dies 210 can include high power chips having maximum operation powers higher than the threshold power value. For example, the stacked dies 210 include at least one of a micro processing chip, a logic control chip, a power management chip, a driver chip, and an analog chip, and may also include at least one of a memory chip and a sensing chip.

As shown in FIG. 2B, in some implementations, a sacrificial layer 212 is deposited on a first surface of the stacked dies, and a plurality of first holes 270 are formed in the sacrificial layer 212 and vertically extend through the stacked dies 210. In some implementations, the carrier wafer 215 is removed before forming the sacrificial layer 212. In some implementations, the carrier wafer 215 is used as the sacrificial layer 212 and the plurality of first holes 270 are formed in the carrier wafer 215. A lithography process can be performed to pattern the first holes using an etch mask (e.g., a photoresist mask and/or a hard mask), and one or more dry etching and/or wet etching processes, such as RIE, can be performed to etch first holes in the sacrificial layer 212. Thus, the first holes 270 extending vertically in the sacrificial layer 212 can be formed.

As shown in FIG. 2B, in some implementations, a plurality of second holes 272 are formed in the sacrificial layer 212 and vertically extend inside the stacked dies 210. A lithography process can be performed to pattern the second holes using an etch mask (e.g., a photoresist mask and/or a hard mask), and one or more dry etching and/or wet etching processes, such as RIE, can be performed to etch second holes in the sacrificial layer 212. Thus, second holes 272 extending vertically in the sacrificial layer 212 can be formed. In some implementations, the plurality of second holes 272 have different dimensions along the vertical direction. The dimensions of the second holes along the vertical direction can be controlled by etching each second hole with different time durations or by back-filling the second holes to achieve a certain vertical dimension. In some implementations, forming the second holes 272 can be performed in a same process of forming the first holes 270. A lateral dimension (e.g., the x-direction) of each first hole 270 is larger than a lateral dimension (e.g., the x-direction) of each second hole 272. In some implementations, the second holes 272 can be sandwiched between two sets of first holes 270, or the second holes 272 can be surrounded by the plurality of first holes 270.

As shown in FIG. 2C, in some embodiments, a first contact structure 280 including a plurality of first channels 282 is formed inside the plurality of first holes 270, for example, by depositing a metal, a ceramic material, or a silicon material, to fill first holes 270 using one or more thin film deposition processes including, but not limited to, CVD, PVD, ALD, or any combination thereof. Each first channel 282 is a continuous channel that extends through the stacked dies. That is, each first channel 282 has a first end in contact with the bottom surface of the bottommost die and a second end in contact with the top surface of the topmost die of the stacked dies. The first end of each first channel 282 has a first lateral dimension (e.g., x-direction), the second end of each first channel 282 has a second lateral dimension (e.g., x-direction), and the first lateral dimension is larger than the second lateral dimension. In some implementations, the first lateral dimension of each first channel 282 is about 2-3 μm. The material of each first channel 282 has a thermal conductive coefficient of no less than 20 W/mK. In some implementations, the material of each first channel is one of a metal, a ceramic material, or a silicon material. In some implementations, the material of each first channel can be one of silicon nitride, aluminum oxide, and silicon carbide. A planarization process, such as CMP, is performed to remove excess first channel 282 that is deposited beyond the top surface of the topmost die.

In some implementations, as shown in FIG. 2C, a second contact structure 285 including a plurality of second channels can be formed inside the plurality of second holes 272, for example, by depositing a metal, a ceramic material, or a silicon material, to fill second holes 272 using one or more thin film deposition processes including, but not limited to, CVD, PVD, ALD, or any combination thereof. Each second channel is a continuous channel that extends vertically inside the stack dies. That is, each second channel has a first end in contact with the bottom surface of the bottommost die and a second end inside the stacked dies without contacting the top surface of the topmost die of the stacked dies. The first end of each second channel of second contact structure 285 has a third lateral dimension (e.g., x-direction), and the third lateral dimension is smaller than the first lateral dimension of the first end of each first channel 282. In some implementations, the third lateral dimension is less than 2 μm. In some implementations, the plurality of second channels have different dimensions along the vertical direction. For example, second channel 285-1 has a first end in contact with the bottom surface of die 202 and a second end inside the die 202 without contacting the top surface of die 202; second channel 285-2 has a first end in contact with the bottom surface of die 202 and a second end inside die 203 without contacting the top surface of die 203; second channel 285-3 has a first end in contact with the bottom surface of die 202 and a second end inside die 203 without contacting the top surface of die 203; and second channel 285-4 has a first end in contact with the top surface of die 202 and a second end inside die 205 without contacting the top surface of die 205. In some implementations, the material of each second channel is one of a metal, a ceramic material, or a silicon material.

In some implementations, the first contact structure 280 and the second contact structure 285 are formed in a same process; or the first contact structure 280 and the second contact structure 285 can be formed in different processes. The first contact structure 280 and the second contact structure 285 can be made from a same material; or the first contact structure 280 and the second contact structure 285 can be made from different materials. In some implementations, the first channel 282 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second channel 285-1 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first width of the first channel 282 and a second width of the second channel 285-1 can be in a range between about 1.5:1 to about 2:1.

The first contact structure 280 and the second contact structure 285 are then polished such that the surface of the first contact structure 280 and the surface of the second contact structure 285 are flush with the bottom surface of die 202. In some implementations, a chemical-mechanical polishing (CMP) is performed to polish the first contact structure 280 and the second contact structure 285.

Referring back to FIG. 6, the method 600 can proceed to operation 604, in which a base die is bonded with the stacked dies. FIG. 2D illustrates a schematic diagram in a perspective side view of an exemplary semiconductor device after operation 604 of the method 600 shown in FIG. 6, in accordance with some implementations of the present disclosure.

As shown in FIG. 2D, a base die 240 can be bonded with a first surface (bottom surface) of the stacked dies 210 through hybrid bonding or direct bonding, such that a surface of the base die 240 is in contact with the first end of each first channel 282 of the first contact structure 280 and in contact with the first end of each second channel of second contact structure 285. The base die 240 can be bonded with the stacked dies 210 through hybrid bonding or direct bonding, which is not limited herein. The base die 240 can be provided with wiring structure 244, which includes first wiring structure 246 and second wiring structure 248 embedded in the base die. The first wiring structure 246 can include any suitable thermal conductive interconnection structures, such as conductive vias and patterned conductive layers, etc., and is configured to transport heat. The first wiring structure 246 is physically connected with the first contact structure 280. For example, as shown in FIG. 2D, the first wiring structure is physically connected with the first channel 282. The second wiring structure 248 is physically connected with the second contact structure 285. For example, as shown in FIG. 2D, the second wiring structure is physically connected with the second channel 285-1. The second wiring structure 248 can include any suitable conductive interconnection structures, such as conductive channels, and configured to transmit electronic signals. In some implementations, the second wiring structure 248 can be configured to transmit both electronic signals and heat. The first wiring structure 246 and the second wiring structure 248 can be isolated from each other.

In some implementations, the first wiring structure 246 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 248 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 246 and a second wiring width of the second wiring structure 248 can be in a range between about 1.5:1 to about 2:1.

Referring back to FIG. 6, the method 600 can proceed to operation 606, in which an interposer is bonded with the base die. FIG. 2E illustrates a schematic diagram in a perspective side view of an exemplary semiconductor device after operation 606 of the method 600 shown in FIG. 6, in accordance with some implementations of the present disclosure.

As shown in FIG. 2E, an interposer 220 can be bonded with a surface (bottom surface) of the base die 240, such that a surface of the interposer 220 is in contact with the wiring structure 244. The interposer 220 can be bonded with the base die 240 through hybrid bonding or direct bonding, which is not limited herein. The interposer 220 can be any suitable semiconductor material having any suitable structure, such as a monocrystalline single-layer material, a polycrystalline silicon (polysilicon) single-layer material, a polysilicon and metal multi-layer material, etc. In some implementations, the interposer 220 is provided with a ball grid array (BGA) 230.

Referring back to FIG. 6, the method 600 can proceed to operation 608, in which a thermal conductive layer is formed on a second surface (top surface) of the stacked dies. The second surface of the stacked dies is opposite to the first surface of the stacked dies in the vertical direction. FIG. 2F illustrates a schematic diagram in a perspective side view of an exemplary semiconductor device after operation 608 of the method 600 shown in FIG. 6, in accordance with some implementations of the present disclosure.

As shown in FIG. 2F, a thermal conductive layer 206 can be formed by depositing a thermal conductive material to cover the top surface of the topmost die of the stacked dies 210, so that the thermal conductive layer 206 is in contact with each first channel 282. The material of the thermal conductive layer 206 has a thermal conductive coefficient of no less than 20 W/mK. In some implementations, the material of the thermal conductive layer 206 is one of a metal, a ceramic material, or a silicon material. In some implementations, the material of each first channel can be one of silicon nitride, aluminum oxide, and silicon carbide.

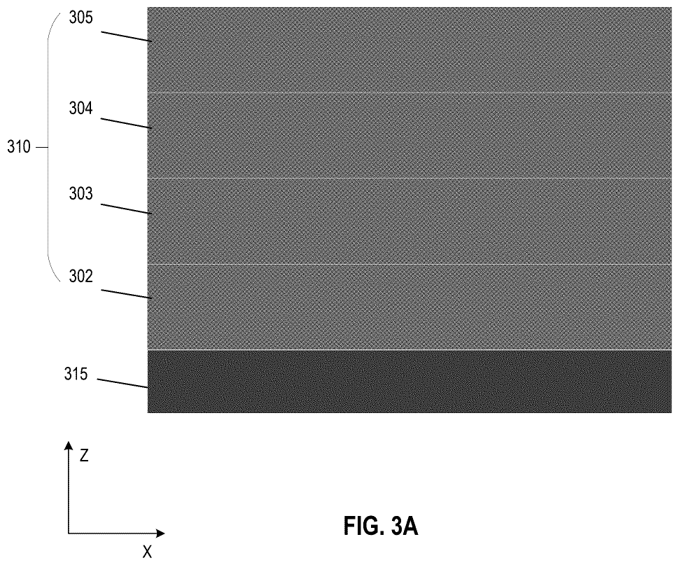

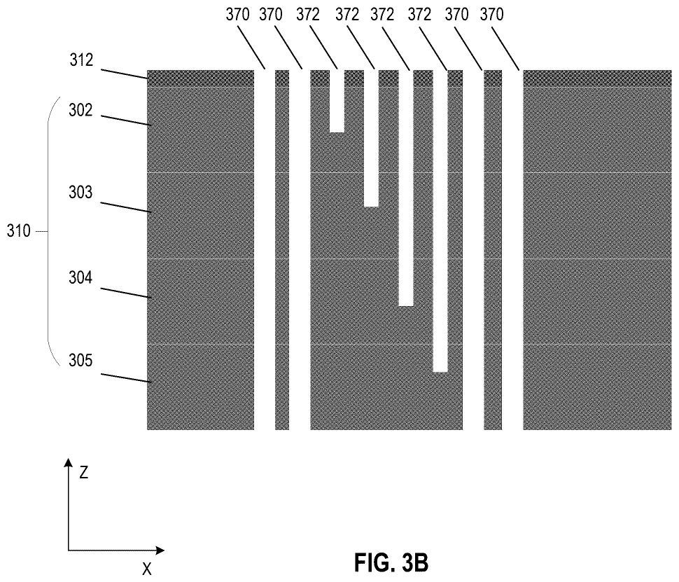

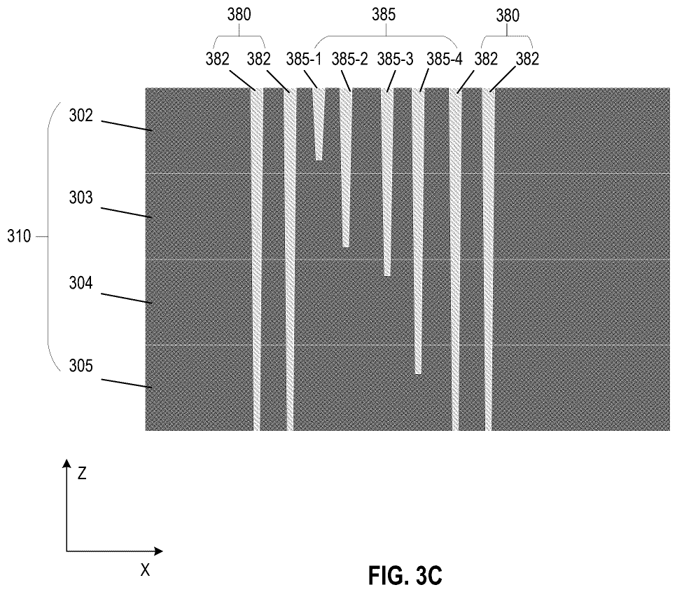

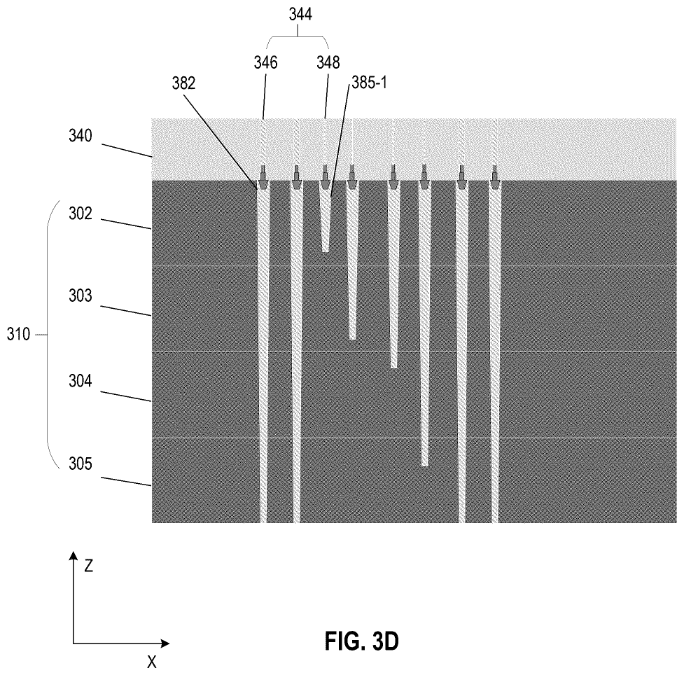

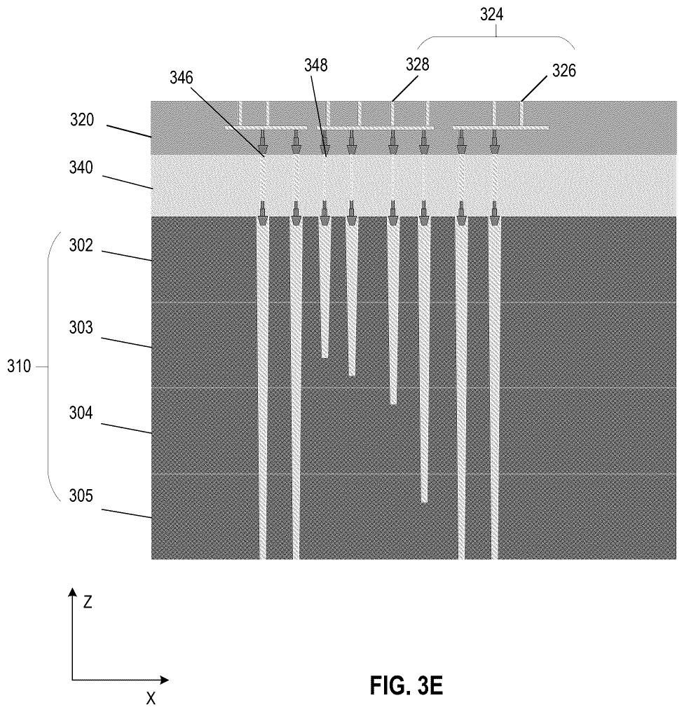

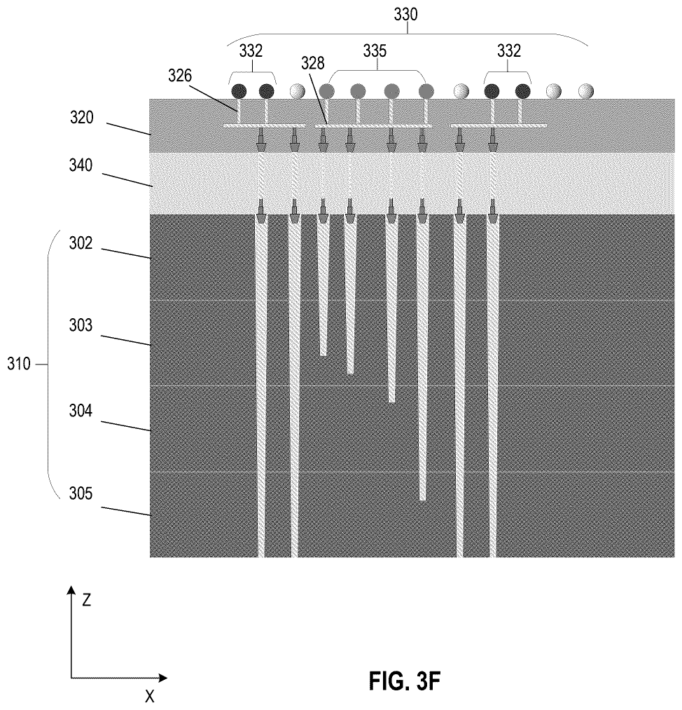

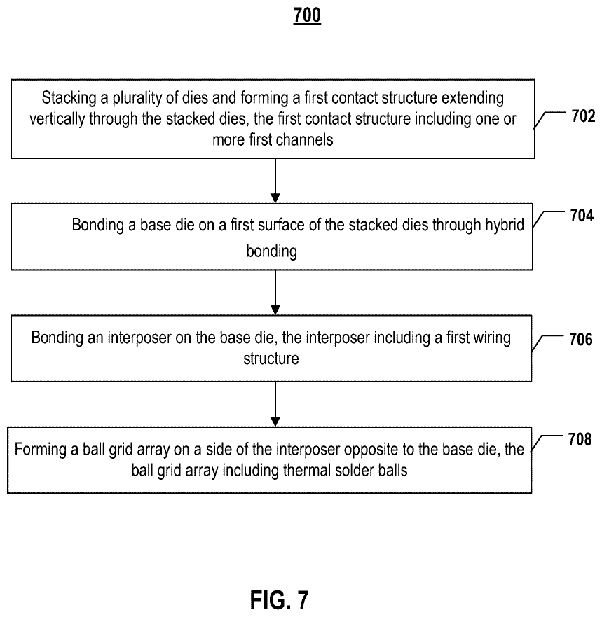

Referring to FIG. 7, a flow diagram of an exemplary method for forming a second semiconductor device is illustrated in accordance with some implementations of the present disclosure. It should be understood that the operations and/or steps shown in FIG. 7 are not exhaustive and that other operations can be performed as well before, after, or between any of the illustrated operations. FIGS. 3A-3F illustrate schematic diagrams in a perspective side view of an exemplary semiconductor device at certain fabricating steps of the method shown in FIG. 7, in accordance with some implementations of the present disclosure.

As shown in FIG. 7, the method 700 starts at operation 702, in which a plurality of dies are stacked along a vertical direction. A first contact structure is formed in the stacked dies. The first contact structure includes a plurality of first channels, each extending vertically through the stacked dies. FIGS. 3A-3C illustrate schematic diagrams in a perspective side view of exemplary semiconductor devices during operation 702 of the method 700 shown in FIG. 7, in accordance with some implementations of the present disclosure.

As shown in FIG. 3A, in some implementations, a plurality of dies are stacked through direct bonding, which forms bonding between surfaces without using intermediate layers, such as solder or adhesives, in a vertical direction on a carrier wafer 315. Exemplarily, as shown in FIG. 3A, die 302, die 303, die 304, and die 305 are stacked vertically on the carrier wafer 315 to form stacked dies 310. In some implementations, the stacked dies 310 can be any suitable semiconductor dies/die including one or more memory dies. The stacked dies 310 can include low power chips having maximum operation powers lower than a threshold power value. The stacked dies 310 can include high power chips having maximum operation powers higher than the threshold power value. For example, the stacked dies 310 include at least one of a micro processing chip, a logic control chip, a power management chip, a driver chip, and an analog chip, and may also include at least one of a memory chip and a sensing chip.

As shown in FIG. 3B, in some implementations, a sacrificial layer 312 is deposited on a first surface of the stacked dies 310, and a plurality of first holes 370 are formed in the sacrificial layer 312 and vertically extend through the stacked dies 310. In some implementations, the carrier wafer 315 is removed before forming the sacrificial layer 312. In some implementations, the carrier wafer 315 is used as the sacrificial layer 312 and the plurality of first holes 270 are formed in the carrier wafer 315. A lithography process can be performed to pattern the first holes using an etch mask (e.g., a photoresist mask and/or a hard mask), and one or more dry etching and/or wet etching processes, such as RIE, can be performed to etch first holes 370 in the sacrificial layer 312. Thus, first holes 370 extending vertically in the sacrificial layer 312 can be formed.

As shown in FIG. 3B, in some implementations, a plurality of second holes 372 are formed in the sacrificial layer 312 and vertically extend inside the stacked dies 310. A lithography process can be performed to pattern the second holes 372 using an etch mask (e.g., a photoresist mask and/or a hard mask), and one or more dry etching and/or wet etching processes, such as RIE, can be performed to etch second holes 372 in the sacrificial layer 312. Thus, second holes 372 extending vertically in the sacrificial layer 312 can be formed. In some implementations, the plurality of second holes 372 have different dimensions along the vertical direction. The dimensions of the second holes 372 along the vertical direction can be controlled by etching each second hole 372 with different time durations or by back-filling the second holes 372 to achieve a certain vertical dimension. In some implementations, forming the second holes 372 can be performed in a same process of forming the first holes 370. A lateral dimension (e.g., the x-direction) of each first hole 370 is larger than a lateral dimension (e.g., the x-direction) of each second hole 372. In some implementations, the second holes 372 can be sandwiched between two sets of first holes 370, or the second holes 372 can be surrounded by the plurality of first holes 370.

As shown in FIG. 3C, in some embodiments, a first contact structure 380 including a plurality of first channels 382 is formed inside the plurality of first holes 370, for example, by depositing a metal, a ceramic material, or a silicon material, to fill first holes 370 using one or more thin film deposition processes including, but not limited to, CVD, PVD, ALD, or any combination thereof. Each first channel 382 is a continuous channel that extends through the stacked dies 310. That is, each first channel 382 has a first end in contact with the bottom surface of the bottommost die and a second end in contact with the top surface of the topmost die of the stacked dies 310. The first end of each first channel 382 has a first lateral dimension (e.g., x-direction), the second end of each first channel 382 has a second lateral dimension (e.g., x-direction), and the first lateral dimension is larger than the second lateral dimension. In some implementations, the first lateral dimension is about 2-3 μm. The material of each first channel 382 has a thermal conductive coefficient of no less than 20 W/mK. In some implementations, the material of each first channel 382 is one of a metal, a ceramic material, or a silicon material. In some implementations, the material of each first channel 382 can be one of silicon nitride, aluminum oxide, and silicon carbide. A planarization process, such as CMP, can be performed to remove excess first channel 382 that is deposited beyond the top surface of the topmost die.

In some implementations, as shown in FIG. 3C, a second contact structure 385 including a plurality of second channels can be formed inside the plurality of second holes 372, for example, by depositing a metal, a ceramic material, or a silicon material, to fill second holes 372 using one or more thin film deposition processes including, but not limited to, CVD, PVD, ALD, or any combination thereof. Each second channel is a continuous channel that extends vertically inside the stack dies 310. That is, each second channel has a first end in contact with the bottom surface of the bottommost die and a second end inside the stacked dies without contacting the top surface of the topmost die of the stacked dies. The first end of each second channel of the second contact structure 385 has a third lateral dimension (e.g., x-direction), and the third lateral dimension is smaller than the first lateral dimension of the first end of each first channel. In some implementations, the third lateral dimension is less than 2 μm. In some implementations, the plurality of second channels have different dimensions along the vertical direction. For example, second channel 385-1 has a first end in contact with the bottom surface of die 302 and a second end inside the die 302 without contacting the top surface of die 302; second channel 385-2 has a first end in contact with the bottom surface of die 302 and a second end inside die 303 without contacting the top surface of die 303; second channel 385-3 has a first end in contact with the bottom surface of die 302 and a second end inside die 303 without contacting the top surface of die 303; and second channel 385-4 has a first end in contact with the top surface of die 302 and a second end inside die 305 without contacting the top surface of die 305. In some implementations, the material of each second channel is one of a metal, a ceramic material, or a silicon material.

In some implementations, the first contact structure 380 and the second contact structure 385 are formed in a same process; or the first contact structure 380 and the second contact structure 385 can be formed in different processes. The first contact structure 380 and the second contact structure 385 can be made from a same material; or the first contact structure 380 and the second contact structure 385 can be made from different materials. In some implementations, the first channel 382 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second channel 385-1 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first width of the first channel 382 and a second width of the second channel 385-1 can be in a range between about 1.5:1 to about 2:1.

The first contact structure 380 and the second contact structure 385 are then polished such that the surface of the first contact structure 380 and the surface of the second contact structure 385 are flush with the bottom surface of die 302. In some implementations, a chemical-mechanical polishing (CMP) is performed to polish the first contact structure 380 and the second contact structure 385.

Referring back to FIG. 7, the method 700 can proceed to operation 704, in which a base die is bonded with the stacked dies. FIG. 3D illustrates a schematic diagram in a perspective side view of an exemplary semiconductor device after operation 704 of the method 700 shown in FIG. 7, in accordance with some implementations of the present disclosure.

As shown in FIG. 3D, a base die 340 can be bonded with a first surface (bottom surface) of the stacked dies 310 through hybrid bonding or direct bonding, such that a surface of the base die 340 is in contact with the first end of each first channel 382 of the first contact structure 380 and in contact with the first end of each second channel of second contact structure 385. The base die 340 can be bonded with the stacked dies 310 through hybrid bonding or direct bonding, which is not limited herein. The base die 340 can be provided with wiring structure 344, which includes first wiring structure 346 and second wiring structure 348 embedded in the base die 340. The first wiring structure 346 can include any suitable thermal conductive interconnection structures, such as conductive vias and patterned conductive layers, etc., and is configured to transport heat. The first wiring structure 346 is physically connected with the first contact structure 380. For example, as shown in FIG. 3D, the first wiring structure 346 is physically connected with the first channel 382. The second wiring structure 348 is physically connected with the second contact structure 385. For example, as shown in FIG. 3D, the second wiring structure 348 is physically connected with the second channel 385-1. The second wiring structure 348 can include any suitable conductive interconnection structures, such as conductive channels, and configured to transmit electronic signals. In some implementations, the second wiring structure 348 can be configured to transmit both electronic signals and heat. The first wiring structure 346 and the second wiring structure 348 can be isolated from each other.

In some implementations, the first wiring structure 346 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 348 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 346 and a second wiring width of the second wiring structure 348 can be in a range between about 1.5:1 to about 2:1.

Referring back to FIG. 7, the method 700 can proceed to operation 706, in which an interposer is bonded with the base die. FIG. 3E illustrates a schematic diagram in a perspective side view of an exemplary semiconductor device after operation 706 of the method 700 shown in FIG. 7, in accordance with some implementations of the present disclosure.

As shown in FIG. 3E, an interposer 320 can be bonded with a surface (bottom surface) of the base die 340, such that a surface of the interposer 320 is in contact with the wiring structure 344. The interposer 320 can be bonded with the base die 340 through hybrid bonding or direct bonding, which is not limited herein. The interposer 320 can be any suitable semiconductor material having any suitable structure, such as a monocrystalline single-layer material, a polycrystalline silicon (polysilicon) single-layer material, a polysilicon and metal multi-layer material, etc. The interposer 320 can be provided with connecting structure 324, which includes first connecting structure 326 and second connecting structure 328 embedded in the interposer 320. The first connecting structure 326 can include any suitable thermal conductive interconnection structures, such as conductive vias and patterned conductive layers, etc., and is configured to transport heat. The second connecting structure 328 can include any suitable conductive interconnection structures, such as conductive channels, and is configured to transmit electronic signals. In some implementations, the second connecting structure 328 can be configured to transmit both electronic signals and heat. The first connecting structure 326 and the second connecting structure 328 can be isolated from each other.

Referring back to FIG. 7, the method 700 can proceed to operation 708, in which a ball grid array (BGA) is formed on a side of the interposer opposite to the base die. FIG. 3F illustrates a schematic diagram in a perspective side view of an exemplary semiconductor device after operation 708 of the method 700 shown in FIG. 7, in accordance with some implementations of the present disclosure.

As shown in FIG. 7F, a ball grid array (BGA) 330 is formed on a side of the interposer 320 opposite to the base die 340. The BGA 330 includes thermal solder balls 332 that are physically connected with the first connecting structure 326 and signal solder balls 335 that are physically connected with the second connecting structure 328. The thermal solder balls 332 and the signal solder balls 335 can include same materials, and can be formed in a same process. For example, the thermal solder balls 332 and the signal solder balls 335 can include any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the thermal solder balls 332 and the signal solder balls 335 can include different materials. For example, the thermal solder balls 332 can include a first material with a high thermal conductive coefficient, while the signal solder balls 335 can include a second material with a high electric conductive coefficient.

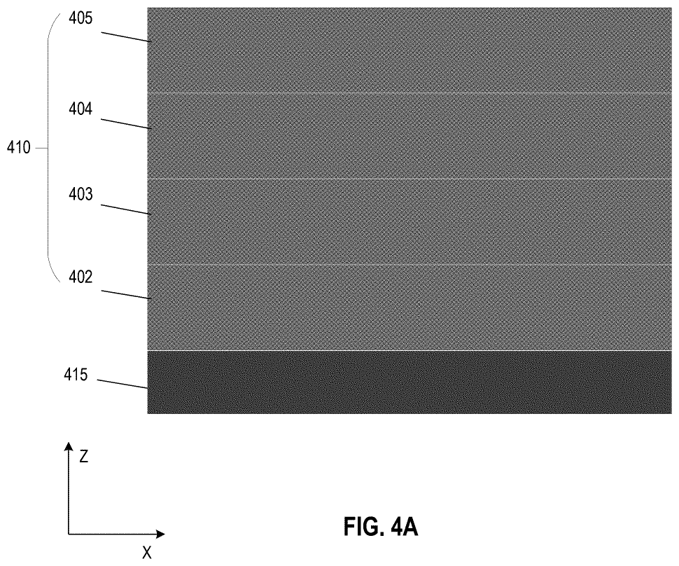

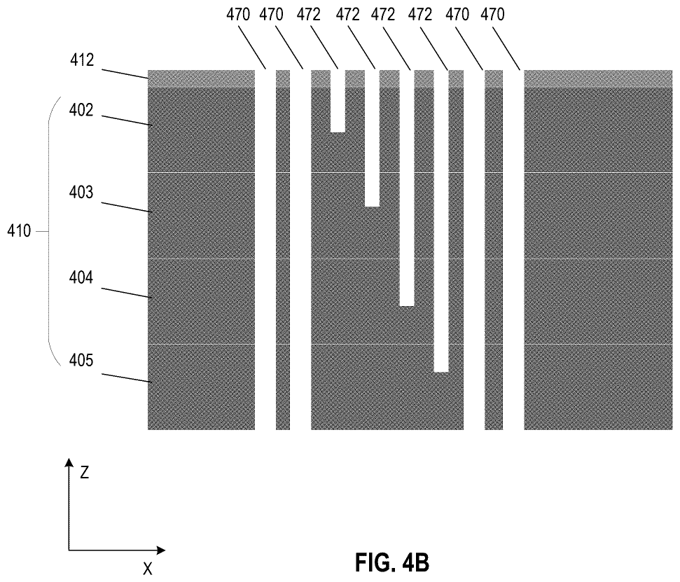

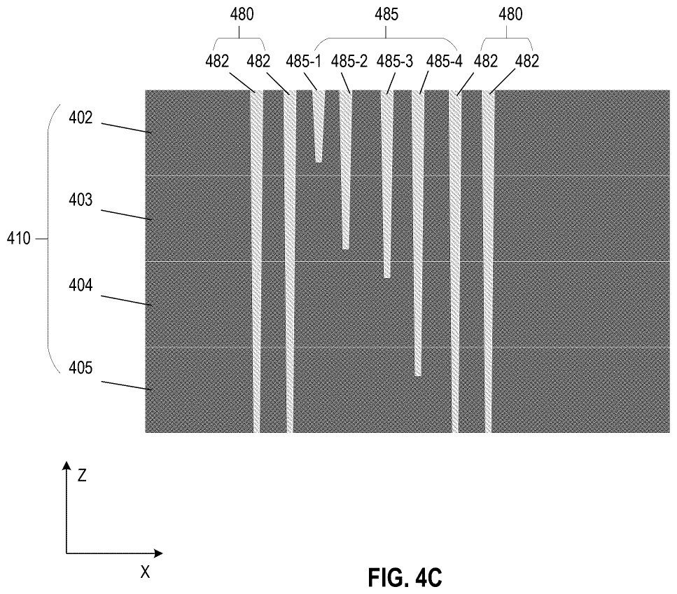

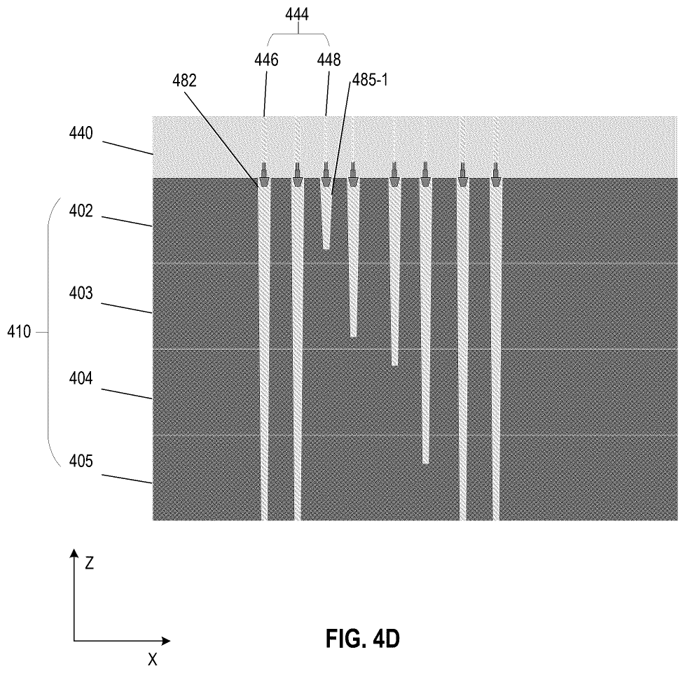

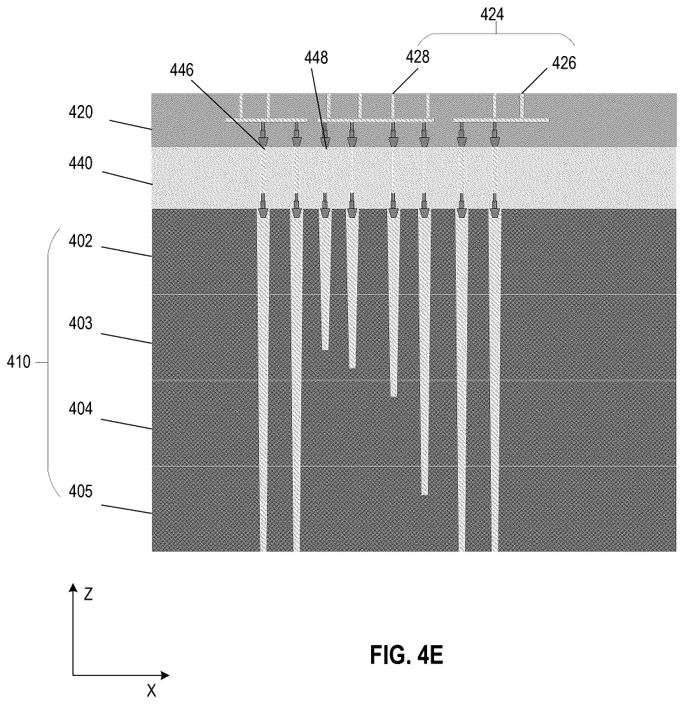

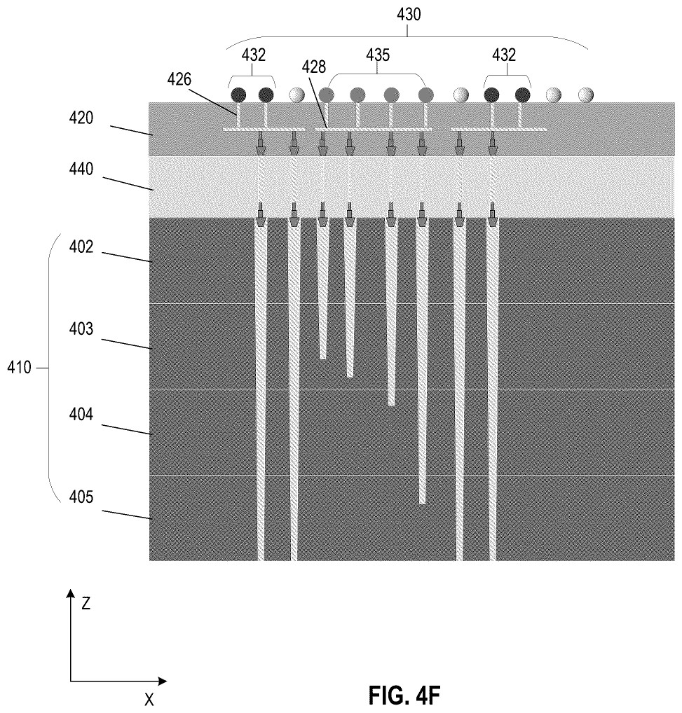

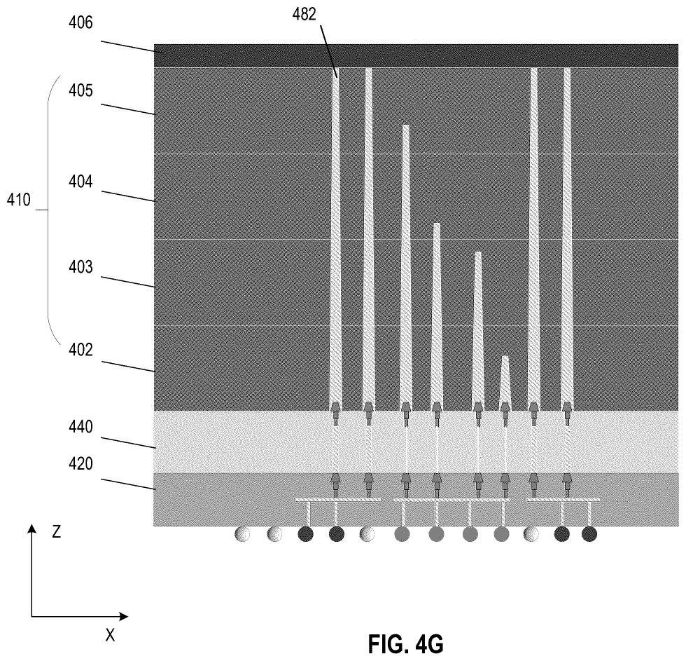

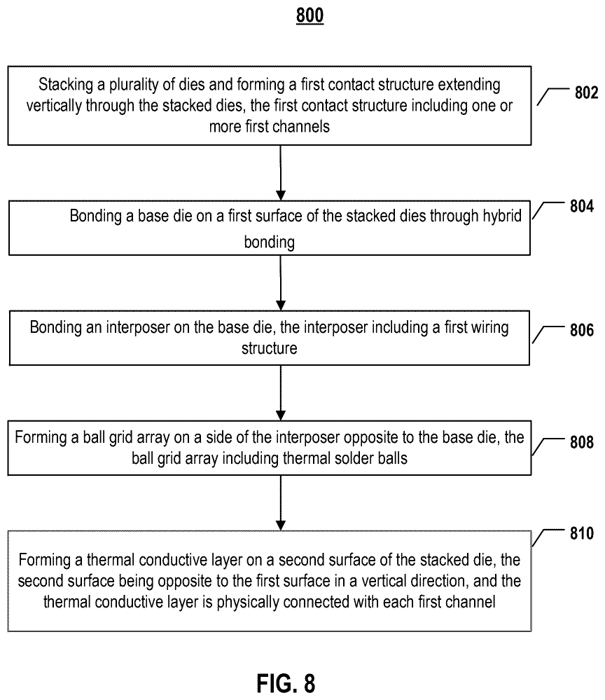

Referring to FIG. 8, a flow diagram of an exemplary method for forming a third semiconductor device is illustrated in accordance with some implementations of the present disclosure. It should be understood that the operations and/or steps shown in FIG. 8 are not exhaustive and that other operations can be performed as well before, after, or between any of the illustrated operations. FIGS. 4A-4G illustrate schematic diagrams in a perspective side view of an exemplary semiconductor device at certain fabricating steps of the method shown in FIG. 8, in accordance with some implementations of the present disclosure.

As shown in FIG. 8, the method 800 starts at operation 802, in which a plurality of dies are stacked along a vertical direction. A first contact structure is formed in the stacked dies. The first contact structure includes a plurality of first channels, each extending vertically through the stacked dies. FIGS. 4A-4C illustrate schematic diagrams in a perspective side view of exemplary semiconductor devices during operation 802 of the method 800 shown in FIG. 8, in accordance with some implementations of the present disclosure.

As shown in FIG. 4A, in some implementations, a plurality of dies are stacked through direct bonding, which forms bonding between surfaces without using intermediate layers, such as solder or adhesives, in a vertical direction on a carrier wafer 415. Exemplarily, as shown in FIG. 4A, die 402, die 403, die 404, and die 405 are stacked vertically on the carrier wafer 415 to form stacked dies 410. In some implementations, the stacked dies 410 can be any suitable semiconductor dies/die including one or more memory dies. The stacked dies 410 can include low power chips having maximum operation powers lower than a threshold power value. The stacked dies 410 can include high power chips having maximum operation powers higher than the threshold power value. For example, the stacked dies 410 include at least one of a micro processing chip, a logic control chip, a power management chip, a driver chip, and an analog chip, and may also include at least one of a memory chip and a sensing chip.

As shown in FIG. 4B, in some implementations, a sacrificial layer 412 is deposited on a first surface of the stacked dies 410, and a plurality of first holes 470 are formed in the sacrificial layer 412 and vertically extend through the stacked dies 410. In some implementations, the carrier wafer 415 is removed before forming the sacrificial layer 412. In some implementations, the carrier wafer 415 is used as the sacrificial layer 412 and the plurality of first holes 470 are formed in the carrier wafer 415. A lithography process can be performed to pattern the first holes using an etch mask (e.g., a photoresist mask and/or a hard mask), and one or more dry etching and/or wet etching processes, such as RIE, can be performed to etch first holes 470 in the sacrificial layer 412. Thus, first holes 470 extending vertically in the sacrificial layer 412 can be formed.

As shown in FIG. 4B, in some implementations, a plurality of second holes 472 are formed in the sacrificial layer 412 and vertically extend inside the stacked dies 410. A lithography process can be performed to pattern the second holes 472 using an etch mask (e.g., a photoresist mask and/or a hard mask), and one or more dry etching and/or wet etching processes, such as RIE, can be performed to etch second holes 472 in the sacrificial layer 412. Thus, second holes 472 extending vertically in the sacrificial layer 412 can be formed. In some implementations, the plurality of second holes 472 have different dimensions along the vertical direction. The dimensions of the second holes 472 along the vertical direction can be controlled by etching each second hole 472 with different time durations or by back-filling the second holes 472 to achieve a certain vertical dimension. In some implementations, forming the second holes 472 can be performed in a same process of forming the first holes 470. A lateral dimension (e.g., the x-direction) of each first hole 470 is larger than a lateral dimension (e.g., the x-direction) of each second hole 472. In some implementations, the second holes 472 can be sandwiched between two sets of first holes 470, or the second holes 472 can be surrounded by the plurality of first holes 470.

As shown in FIG. 4C, in some embodiments, a first contact structure 480 including a plurality of first channels 482 is formed inside the plurality of first holes 470, for example, by depositing a metal, a ceramic material, or a silicon material, to fill first holes 470 using one or more thin film deposition processes including, but not limited to, CVD, PVD, ALD, or any combination thereof. Each first channel 482 is a continuous channel that extends through the stacked dies 410. That is, each first channel 482 has a first end in contact with the bottom surface of the bottommost die and a second end in contact with the top surface of the topmost die of the stacked dies 410. The first end of each first channel 482 has a first lateral dimension (e.g., x-direction), the second end of each first channel 482 has a second lateral dimension (e.g., x-direction), and the first lateral dimension is larger than the second lateral dimension. In some implementations, the first lateral dimension is about 2-3 μm. The material of each first channel 482 has a thermal conductive coefficient of no less than 20 W/mK. In some implementations, the material of each first channel 482 is one of a metal, a ceramic material, or a silicon material. In some implementations, the material of each first channel 482 can be one of silicon nitride, aluminum oxide, and silicon carbide. A planarization process, such as CMP, can be performed to remove excess first channel 482 that is deposited beyond the top surface of the topmost die.

In some implementations, as shown in FIG. 4C, a second contact structure 485 including a plurality of second channels can be formed inside the plurality of second holes 472, for example, by depositing a metal, a ceramic material, or a silicon material, to fill second holes 472 using one or more thin film deposition processes including, but not limited to, CVD, PVD, ALD, or any combination thereof. Each second channel is a continuous channel that extends vertically inside the stack dies 410. That is, each second channel has a first end in contact with the bottom surface of the bottommost die and a second end inside the stacked dies without contacting the top surface of the topmost die of the stacked dies. The first end of each second channel of the second contact structure 485 has a third lateral dimension (e.g., x-direction), and the third lateral dimension is smaller than the first lateral dimension of the first end of each first channel. In some implementations, the third lateral dimension is less than 2 μm. In some implementations, the plurality of second channels have different dimensions along the vertical direction. For example, second channel 485-1 has a first end in contact with the bottom surface of die 402 and a second end inside the die 402 without contacting the top surface of die 402; second channel 485-2 has a first end in contact with the bottom surface of die 402 and a second end inside die 403 without contacting the top surface of die 403; second channel 485-3 has a first end in contact with the bottom surface of die 402 and a second end inside die 403 without contacting the top surface of die 403; and second channel 485-4 has a first end in contact with the top surface of die 402 and a second end inside die 405 without contacting the top surface of die 405. In some implementations, a material of each second channel is one of a metal, a ceramic material, or a silicon material.

In some implementations, the first contact structure 480 and the second contact structure 485 are formed in a same process; or the first contact structure 480 and the second contact structure 485 can be formed in different processes. The first contact structure 480 and the second contact structure 485 can be made from a same material; or the first contact structure 480 and the second contact structure 485 can be made from different materials. In some implementations, the first channel 482 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second channel 485-1 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first width of the first channel 482 and a second width of the second channel 485-1 can be in a range between about 1.5:1 to about 2:1.

The first contact structure 480 and the second contact structure 485 are then polished such that the surface of the first contact structure 480 and the surface of the second contact structure 485 are flush with the bottom surface of die 402. In some implementations, a chemical-mechanical polishing (CMP) is performed to polish the first contact structure 480 and the second contact structure 485.

Referring back to FIG. 8, the method 800 can proceed to operation 804, in which a base die is bonded with the stacked dies. FIG. 4D illustrates a schematic diagram in a perspective side view of an exemplary semiconductor device after operation 804 of the method 800 shown in FIG. 8, in accordance with some implementations of the present disclosure.

As shown in FIG. 4D, a base die 440 can be bonded with a first surface (bottom surface) of the stacked dies 410 through hybrid bonding or direct bonding, such that a surface of the base die 440 is in contact with the first end of each first channel 482 of the first contact structure 480 and in contact with the first end of each second channel of second contact structure 485. The base die 440 can be bonded with the stacked dies 410 through hybrid bonding or direct bonding, which is not limited herein. The base die 440 can be provided with wiring structure 444, which includes first wiring structure 446 and second wiring structure 448 embedded in the base die 440. The first wiring structure 446 can include any suitable thermal conductive interconnection structures, such as conductive vias and patterned conductive layers, etc., and is configured to transport heat. The first wiring structure 446 is physically connected with the first contact structure 480. For example, as shown in FIG. 4D, the first wiring structure 446 is physically connected with the first channel 482. The second wiring structure 448 is physically connected with the second contact structure 485. For example, as shown in FIG. 4D, the second wiring structure 448 is physically connected with the second channel 485-1. The second wiring structure 448 can include any suitable conductive interconnection structures, such as conductive channels, and configured to transmit electronic signals. In some implementations, the second wiring structure 448 can be configured to transmit both electronic signals and heat. The first wiring structure 446 and the second wiring structure 448 can be isolated from each other.

In some implementations, the first wiring structure 446 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. The second wiring structure 448 can comprise any suitable conductive materials, such as Ag, Cu, aluminum (Al), aluminum nitride, silicon carbide, W, graphite, zinc (Zn), combinations thereof, and/or other materials known to those skilled in the art. In some implementations, a ratio between a first wiring width of the first wiring structure 446 and a second wiring width of the second wiring structure 448 can be in a range between about 1.5:1 to about 2:1.

Referring back to FIG. 8, the method 800 can proceed to operation 806, in which an interposer is bonded with the base die. FIG. 4E illustrates a schematic diagram in a perspective side view of an exemplary semiconductor device after operation 806 of the method 800 shown in FIG. 8, in accordance with some implementations of the present disclosure.

As shown in FIG. 4E, an interposer 420 can be bonded with a surface (bottom surface) of the base die 440, such that a surface of the interposer 420 is in contact with the wiring structure 444. The interposer 420 can be bonded with the base die 440 through hybrid bonding or direct bonding, which is not limited herein. The interposer 420 can be any suitable semiconductor material having any suitable structure, such as a monocrystalline single-layer material, a polycrystalline silicon (polysilicon) single-layer material, a polysilicon and metal multi-layer material, etc. The interposer 420 can be provided with connecting structure 424, which includes first connecting structure 426 and second connecting structure 428 embedded in the interposer 420. The first connecting structure 426 can include any suitable thermal conductive interconnection structures, such as conductive vias and patterned conductive layers, etc., and is configured to transport heat. The second connecting structure 428 can include any suitable conductive interconnection structures, such as conductive channels, and is configured to transmit electronic signals. In some implementations, the second connecting structure 428 can be configured to transmit both electronic signals and heat. The first connecting structure 426 and the second connecting structure 328 can be isolated from each other.

Referring back to FIG. 8, the method 800 can proceed to operation 808, in which a ball grid array (BGA) is formed on a side of the interposer opposite to the base die. FIG. 4F illustrates a schematic diagram in a perspective side view of an exemplary semiconductor device after operation 808 of the method 800 shown in FIG. 8, in accordance with some implementations of the present disclosure.

As shown in FIG. 4F, a ball grid array (BGA) 430 is formed on a side of the interposer 420 opposite to the base die 440. The BGA 430 includes thermal solder balls 432 that are physically connected with the first connecting structure 426 and signal solder balls 435 that are physically connected with the second connecting structure 428. The thermal solder balls 432 and the signal solder balls 435 can include same materials, and can be formed in a same process. For example, the thermal solder balls 432 and the signal solder balls 435 can include any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the thermal solder balls 432 and the signal solder balls 435 can include different materials. For example, the thermal solder balls 432 can include a first material with a high thermal conductive coefficient, while the signal solder balls 435 can include a second material with a high electric conductive coefficient.

Referring back to FIG. 8, the method 800 can proceed to operation 810, in which a thermal conductive layer is formed on a second surface (top surface) of the stacked dies. The second surface of the stacked dies is opposite to the first surface of the stacked dies in the vertical direction. FIG. 4G illustrates a schematic diagram in a perspective side view of an exemplary semiconductor device after operation 810 of the method 800 shown in FIG. 8, in accordance with some implementations of the present disclosure.

As shown in FIG. 4G, a thermal conductive layer 406 can be formed by depositing a thermal conductive material to cover the top surface of the topmost die of the stacked dies 410, so that the thermal conductive layer 406 is in contact with each first channel 482. A material of the thermal conductive layer 406 has a thermal conductive coefficient of no less than 20 W/mK. In some implementations, the material of the thermal conductive layer 406 is one of a metal, a ceramic material, or a silicon material. In some implementations, the material of each first channel can be one of silicon nitride, aluminum oxide, and silicon carbide. In some implementations, the thermal conductive layer 406 can include any suitable thermal conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art.

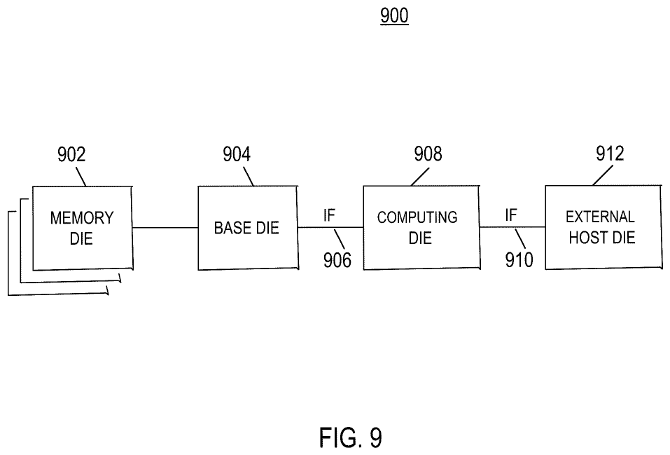

This disclosure further provides a system, as described in International Application No. PCT/CN2024/078561, filed on Feb. 26, 2024, which is incorporated by reference herein. FIG. 9 illustrates a block diagram of an example system 900 having one or more semiconductor devices (e.g., memory devices), in accordance with some implementations of the present disclosure. The system 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, the system 900 can include one or more memory die 902, a base device 904, a computing device 908, and an external host device 912. In some implementations, each of devices 902, 904, 908, and 912 can be a die or multiple dies stacked together. Each of devices 902, 904, 908, and 912 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some embodiments, each die is encapsulated in a protective package, providing physical support, protection from environmental factors, and connections (e.g., through pins or solder balls) to external devices or system.

Memory die 902 can include any memory device disclosed herein, such as a memory device (e.g., a 3D memory device) based on any one of semiconductor structures as described with respect to FIGS. 1A-1C, FIGS. 2A-2F, FIGS. 3A-3F, and FIGS. 4A-4G. In some implementations, memory die 902 includes one or more dynamic random-access memory (DRAM) devices. In some implementations, memory die 902 includes one or more NAND Flash memories. In some implementations, memory die 902 can include a high bandwidth memory (HBM). In some implementations, memory die 902 can be stacked together, e.g., as described with further details with respect to FIGS. 1A-1C, FIGS. 2A-2F, FIGS. 3A-3F, and FIGS. 4A-4G. In some implementations, memory die 902 can include a combination of one or more HBM devices.

Base die 904 (also referred to as a logic die or a buffer die) can include buffer circuitry and test logic for memory die 902. Base die 904 can be configured to provide physical layer communication protocols (e.g., IEEE-1500) between memory die 902 and computing die 908. Base die 904 can be configured to transmit data between memory die 902 and computing die 908 based on control commands and addresses from computing die 908.

Computing die 908 can be a logic device and can include at least one processor of an electronic device, such as a central processing unit (CPU), a graphics processing unit (GPU), an application-specific integrated circuit (ASIC), or a system-on-chip (SoC), such as an application processor (AP). Computing die 908 can be configured to send or receive data to or from memory die 902. Computing die 908 is coupled to base die 904 through an interface (IF) 906. Interface 906 can include connections provided by bonding contacts or an interposer (e.g., as described with respect to FIGS. 1A-1C, FIGS. 2A-2F, FIGS. 3A-3F, and FIGS. 4A-4G). In some implementations, interface 906 includes connections provided by any suitable combination of the aforementioned techniques.

System 900 can further include the external host die 912 coupled to computing die 908 through an interface (IF) 910. For example, external host die 912 can be a computer, and computing die 908 can be a CPU of the computer. In this example, interface 910 includes connections provided by a mainboard of the computer that are coupled to the CPU. As another example, external host die 912 is a graphics card, computing die 908 is a GPU of the graphics card, and interface 910 includes connections provided by a printed circuit board (PCB) of the graphics card that are coupled to the GPU.

System 900 may further include a memory controller (a.k.a., a controller circuit, which is not shown in FIG. 9) coupled to memory die 902. In some implementations, the memory controller is located in the computing die 908. Consistent with implementations of the present disclosure, the memory controller can include conductive interconnections through a cover layer that are in contact with conductive pads in a conductive pad layer, and the memory controller can be coupled to memory die 902 through at least one of the conductive interconnections. The memory controller is configured to control memory die 902. For example, the memory controller may be configured to operate channel structures via word lines. The memory controller can manage data stored in memory die 902 and communicate with computing die 908.

In some implementations, the memory controller is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller is designed/configured for operating in a high duty cycle environment SSDs or embedded multi-media-cards (eMMCs) used as data storage for mobile devices, such as smartphones, tablets, laptop computers, etc., and enterprise storage arrays. The memory controller can be configured to control operations of memory die 902, such as read, erase, and program (or write) operations. The memory controller can also be configured to manage various functions with respect to the data stored or to be stored in memory die 902 including, but not limited to bad-block management, garbage collection, logical-to-physical address conversion, wear leveling, etc. In some implementations, the memory controller is further configured to process error correction codes (ECCs) with respect to the data read from or written to memory die 902. In some other implementations, the base die 904 instead of the memory controller is configured to process ECCs. Any other suitable functions may be performed by the memory controller as well, for example, formatting memory die 902.

The memory controller can communicate with an external device (e.g., computing die 908) according to a particular communication protocol. For example, the memory controller may communicate with the external device through at least one of various interface protocols, such as a USB protocol, an MMC protocol, a peripheral component interconnection (PCI) protocol, a PCIexpress (PCTe or PCI-e) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller and one or more memory die 902 can be integrated into various types of storage devices, for example, be included in the same package, such as a universal Flash storage (UFS) package or an eMMC package. That is, system 900 can be implemented and packaged into different types of end electronic products. For example, the memory controller and a single memory die 902 may be integrated into a memory card. The memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

It is noted that, although not shown, the above descripted methods can further comprise any other suitable operations to further form semiconductor devices. For example, the formed semiconductor devices can be attached to a printed circuit board (PCB).

The present disclosure provides semiconductor devices with a high thermal conductivity. In the era of great computing power and artificial intelligence (AI), the von Neumann architecture that combines high-bandwidth memory (HBM) with GPU remains the mainstream in the high-performance chip market. However, the high amount of heat generated by the stacked HBM is an urgent issue that needs to be addressed. In the traditional HBM architecture, as the number of stacked DRAM layers increases, the heat dissipation for different layers of DRAM varies, which can easily lead to slow heat dissipation for DRAMs located in the middle, causing a decline in performance. Because DRAM needs to continuously perform read and write operations, it tends to generate heat during operation. The stacked structure of HBM limits the heat dissipation of the DRAM located in the middle layers.

In the semiconductor devices provided by this disclosure, the heat generated during the operation of HBM can be rapidly dissipated through first channels to prevent localized overheating. The number of I/O channels can be significantly increased. The first channels have relatively large lateral dimensions, extend through the entire stacked dies, do not carry out data transmission functions, and act as a thermal conduit to transfer heat. Compared to prior art, the current solution achieves better internal heat dissipation inside stacked dies without increasing the chip area of the HBM.

The foregoing description of the specific implementations will so fully reveal the general nature of the present disclosure that others can, by applying knowledge within the skill of the art, readily modify and/or adapt, for various applications, such specific implementations, without undue experimentation, and without departing from the general concept of the present disclosure. Therefore, such adaptations and modifications are intended to be within the meaning and range of equivalents of the disclosed implementations, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all exemplary implementations of the present disclosure as contemplated by the inventor(s), and thus, are not intended to limit the present disclosure and the appended claims in any way.

The breadth and scope of the present disclosure should not be limited by any of the above-described exemplary implementations, but should be defined only in accordance with the following claims and their equivalents.

What is claimed is:

1. A semiconductor device, comprising:
a plurality of dies stacked in a vertical direction;
a thermal conductive layer deposited on a top surface of a topmost die;
a base die located on a bottom surface of a bottommost die; and
a first contact structure extending vertically through the plurality of dies,
wherein the first contact structure comprises one or more first channels, each first channel having a first end being in contact with the base die and having a second end being in contact with the thermal conductive layer.

2. The semiconductor device according to claim 1, further comprising a second contact structure extending vertically inside the plurality of dies, wherein the second contact structure comprises one or more second channels, each second channel extending vertically and being in contact with the base die without contacting the thermal conductive layer.

3. The semiconductor device according to claim 2, wherein the base die comprises a wiring structure including a first wiring structure and a second wiring structure, wherein the first wiring structure is configured to transport heat and the second wiring structure is configured to transmit electronic signals.

4. The semiconductor device according to claim 3, further comprising:
an interposer on a side of the base die opposite to the plurality of dies, wherein the interposer comprises a ball grid array on a side of the interposer opposite to the base dies.

5. The semiconductor device according to claim 4, wherein the ball grid array comprises:
one or more thermal solder balls in connection with the first wiring structure; and
one or more signal solder balls in connection with the second wiring structure.

6. The semiconductor device according to claim 2, wherein each of the first channel and the second channel is a continuous structure along the vertical direction.

7. The semiconductor device according to claim 2, wherein the second contact structure is surrounded by the first contact structure.

8. A semiconductor device, comprising:
a plurality of dies stacked in a vertical direction;
an interposer located on a bottom surface of a base die, wherein the interposer comprises a wiring structure including a first wiring structure and a second wiring structure; and
a first contact structure extending vertically through the plurality of dies, wherein the first contact structure comprises one or more first channels, each first channel having a first end being in contact with the interposer and having a second end being in contact with a top surface of a topmost die.

9. The semiconductor device according to claim 8, further comprising:
a second contact structure extending vertically inside the plurality of dies, wherein the second contact structure comprises one or more second channels, each second channel extending vertically and being in contact with the interposer without contacting the top surface of the topmost die.

10. The semiconductor device according to claim 8, further comprising:
a ball grid array on a side of the interposer opposite to the plurality of dies.

11. The semiconductor device according to claim 10, wherein the ball grid array comprises:
one or more thermal solder balls in contact with the first wiring structure, wherein the first wiring structure is configured to transport heat; and
one or more signal solder balls in contact with the second wiring structure, wherein the second wiring structure is configured to transmit electronic signals.

12. The semiconductor device according to claim 9, wherein each of the first channel and the second channel is a continuous structure along the vertical direction.

13. The semiconductor device according to claim 9, wherein the second contact structure is surrounded by the first contact structure.

14. A method of forming a semiconductor device, comprising:
stacking a plurality of dies in a vertical direction;
depositing a sacrificial layer on a first surface of the stacked dies, and forming a plurality of first holes in the sacrificial layer;
forming, using the plurality of first holes, a first contact structure extending vertically through the stacked dies, wherein the first contact structure comprises one or more first channels;
bonding a base die on the first surface of the stacked dies through hybrid bonding;
bonding an interposer on the base die, wherein the interposer comprises a wiring structure;
connecting each first channel with the wiring structure; and
forming a thermal conductive layer on a second surface of the stacked die, wherein the second surface is opposite to the first surface in the vertical direction, and the thermal conductive layer is physically connected with each first channel.

15. The method according to claim 14, further comprising:
forming a plurality of second holes in the sacrificial layer;
forming, using the plurality of second holes, a second contact structure extending vertically inside the stacked dies, wherein the second contact structure comprises one or more second channels; and
connecting each second channel with the interposer without physically contacting the thermal conductive layer.

16. The method according to claim 15, further comprising:
forming a ball grid array on a side of the interposer opposite to the stacked dies.

17. The method according to claim 16, wherein the wiring structure comprises a first wiring structure configured to transport heat and a second wiring structure configured to transmit electronic signals, and forming the ball grid array comprises:
forming a plurality of thermal solder balls in contract with the first wiring structure; and
forming a plurality of signal solder balls in contact with the second wiring structure.

18. The method according to claim 15, wherein forming the first contact structure comprises forming each first channel continuously extending along the vertical direction; and
forming the second contact structure comprises forming each second channel continuously extending along the vertical direction.

19. The method according to claim 15, wherein forming the second contact structure comprises forming the second contact structure surrounded by the first contact structure.

20. The method according to claim 15, further comprising forming each first channel with a first end having a first lateral dimension and a second end having a second lateral dimension, wherein the first end of each first channel is in contact with the base die, the second end of each first channel is in contact with the thermal conductive layer, and the first lateral dimension is larger than the second lateral dimension.
